(19) United States
(12) Patent Application Publication
(10) Pub. No.: US 2002/0038510 A1
(43) Pub. Date: Apr. 4, 2002

(54) Method for detecting line width defects in electrical circuit inspection

(75) Inventors: Nissim Savareigo, Ashdod (IL); Hila Shteinberg, Petech Tikva (IL)

Correspondence Address: SUGHRUE, MION, ZINN, MACPEAK & SEAS, PLLC, 2100 Pennsylvania Avenue, N.W., Washington, DC, 20037-3213, US

(73) Assignee: ORBOTECH, LTD

(21) Appl. No.: 09/968,878

(22) Filed: Oct. 3, 2001

Related U.S. Application Data
(60) Provisional application No. 60/237,805, filed on Oct. 4, 2000.

(51) Int. Cl. H01L 21/00; H01L 21/66; G01R 31/26

(52) U.S. Cl. 29/846; 438/4; 438/14; 29/593

(57) ABSTRACT

An automated optical inspection method detects width defects by employing locally applied width information. A defect determination is based on proximal width information of nearby parts of a conductor. Automated optical inspection systems inspect the surfaces of patterned objects for line width defects, employing line width data that is at least partially obtained automatically from analyzing a reference image of a non-defective patterned object.

### CROSS-REFERENCE TO RELATED APPLICATIONS.

This application claims the benefit of U.S. Provisional Application No. 60/237,805, filed Oct. 4, 2000. Application 60/237,805 is incorporated herein by reference in its entirety.

### FIELD OF THE INVENTION

This description generally relates to the field of electrical circuit inspection. More particularly, the field of interest involves systems and methods for identifying line width defects.

### BACKGROUND OF THE INVENTION

To ensure production quality, printed circuit boards are inspected for line width defects using automated optical inspection. A conventional approach has been to inspect the width of conductors for compliance with one or more predetermined target widths, which are applied in a global manner to an entire circuit board under inspection. This approach can be problematic for boards having conductors formed at different line widths, particularly those boards for which the respective width tolerances of some conductors overlap.

### SUMMARY OF THE INVENTION.

A general aspect of the invention relates to an automated optical inspection system, method, and apparatus that detects width defects by employing locally applied width information. One way that this is done is by making a defect determination based on width information of nearby parts of a conductor. To put it another way, the determination is a relative one based on proximal width information.

Another general aspect of the invention relates to automated optical inspection systems, and methods used in such systems, operative to inspect the surfaces of patterned objects for line width defects, employing line width data that is at least partially obtained automatically from analyzing a reference image of a non-defective patterned object. A typical application of such automated optical inspection systems and methods is the inspection of electrical circuits.

Another general aspect of the invention relates to a pattern inspection system and method that employs a simplified set up mechanism. The system is operative to evaluate pattern portions for width defects without the necessity of inputting one or more desired width parameters. In preferred embodiments of the invention this is accomplished by determining a desired width from the analysis of a known to be good “golden” reference, and by employing proximal width information in conjunction with parameters relating to acceptable proximal width changes. Certain not acceptable proximal changes in width constitute width defects.

Another general aspect of the invention relates to a system and method operative to detect line width defects in patterns on objects, for example circuit boards, without a prior knowledge of desired line widths. In some embodiments of the invention, this is accomplished by determining line widths in a pattern to be inspected and then analyzing the line widths with reference to one or more rules defining permitted and not permitted width configurations of the lines. Thus, for example, a sudden narrowing of a line which is located in between two portions of the line having generally the same width may be deemed a line width defect.

Another general aspect of the invention relates to an inspection system and method operative to detect line width defects on linear pattern portions which have a continuously changing width. In various embodiments of the invention this is done by obtaining line width information for linear pattern portions of a known to be acceptable reference pattern at a plurality of locations, and then calculating slope information therefrom. Width information is obtained for a plurality locations along linear pattern portion of an pattern to be inspected. Deviations in the slope are indicative of defects.

Another aspect of the invention relates to a system and method for detecting protrusion defects along linear pattern portions in a pattern to be inspected, for example circuit boards. Regions in between selected pattern portions, e.g. the substrate in between conductors in a circuit board, is artificially defined in an image as a pseudo pattern portion. The pseudo pattern portion is evaluated for line width defects, such as indentions. Indentations in the pseudo pattern portion are in essence protrusions in pattern portions.

Still another general aspect of the invention relates to manufacturing circuit boards by depositing patterns on printed circuit boards and then using various inspection information, such as relating to width defects detected based proximal width analysis, in order to improve manufacturing processes, or in order to repair or discard defective printed circuit boards.

### BRIEF DESCRIPTION OF THE DRAWINGS

FIG. 1 shows a high level overview of a system according to the invention.

FIG. 2 shows a representation of a pattern being inspected, with a nick.

FIG. 3 shows the same pattern as in FIG. 2, but without the nick.

FIG. 4 illustrates the pattern of FIG. 3 after the width of the pattern has been determined.

FIG. 5 illustrates vector identification.

FIG. 6 is a flow diagram of an inspection method in accordance with an embodiment of the invention.

FIG. 7 is a segment of a defective conductor portion in pattern.

FIG. 8 is the segment of the defective conductor of FIG. 7 showing measured width.

FIG. 9 shows vector identification in the segment of FIG. 7.

FIG. 10 is a look-up table (LUT) employed in a preferred embodiment of the invention.

FIG. 11 illustrates use of the LUT of FIG. 10 on the segment of FIG. 9.

FIG. 12 illustrates width indicia obtained for the entire segment of FIG. 9.

FIG. 13 illustrates the identification of vector portions in the segment of FIG. 9.

FIGS. 14A-14E show erosion of a conductor portion, width recordal and vector identification in accordance with a preferred embodiment of the invention.

FIG. 15 is a modified look-up table (LUT) employed in another preferred embodiment of the invention.

FIG. 16 illustrates a way to select a value in the LUT of FIG. 15.

FIG. 17 illustrates an embodiment of the invention operative to detect the presence of protrusions in patterns.

FIGS. 18 and 19 are flow diagrams of a preferred embodiment of the invention employing learn and inspection phases.

FIG. 20 is a block diagram of a circuit board fabrication and inspection system in accordance with a preferred embodiment.

FIG. 21 is a flow diagram of the system shown in FIG. 20.

FIG. 22 is a block diagram of another system for fabrication and inspection of circuit boards in accordance with a preferred embodiment.

FIG. 23 is flow diagram of the system shown in FIG. 22.

FIG. 24 shows a further exemplary pattern 700 subjected to the inspection operation according to FIG. 6.

FIG. 25 is a schematic drawing of hardware employed in an embodiment using a lookup table in a preferred mode of operation.

FIG. 26 is an illustration of a properly formed conductor having a continuously changing width.

FIG. 27 illustrates the detection of defects in conductors having a continuously changing width.

FIG. 28 also illustrates the detection of defects in conductors having a continuously changing width.

### DETAILED DESCRIPTION OF PREFERRED EMBODIMENTS

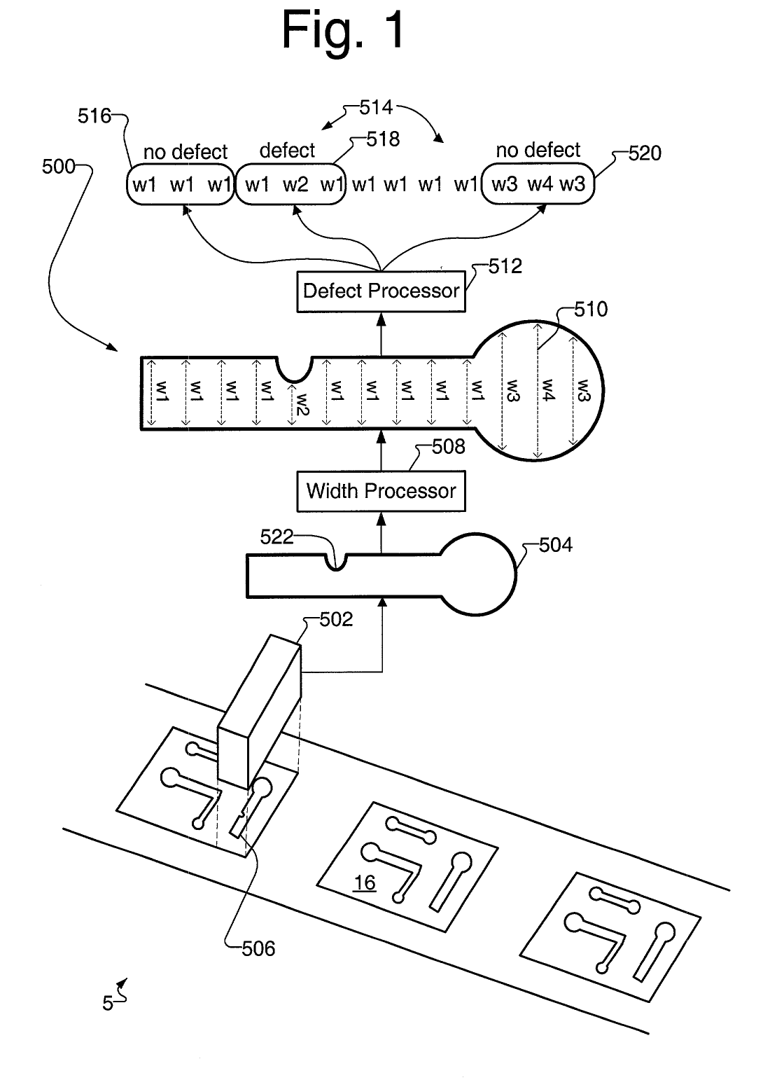

Reference is made to FIG. 1 which shows a high level overview of an inspection system 500 for inspecting a circuit board 16, according to an embodiment of the invention. An imaging processor 502 acquires an image 504 of a pattern 506 (i.e., a board pattern) of the circuit board 16. The width processor 508 analyzes image 504 to obtain width information 510 relating to the pattern 506, for example using any suitable width detection algorithms, and preferably erosion and dilation based morphological width detection algorithms such as are employed in the V-309™ and INSPIRE™ automated optical inspection systems available from Orbotech of Yavne, Israel. A defect processor 512 makes a defect determination 514 for the board pattern 506 based on an analysis of proximal width information for a sequence of selected locations in the board pattern.

Thus, in the example seen in FIG. 1, width information 510 is acquired for a sequence of selected locations in image 504. Proximal locations exhibiting a generally uniform width, such as locations 516 shown as having a width W1, are indicated as being non-defective. However, other proximal locations, such as locations 518 is and 520, having a non-uniform width may, or may not, be defective depending on the location of the width non-uniformity, the pattern of width non-uniformity among proximal locations, and other considerations. For example, in some embodiments of the invention, a reduction in width relative to a uniform width (e.g. defect 518) is a reportable defect, while an increase in width relative to a uniform width (e.g. no defect 520) is not a reportable defect.

The determination of which patterns of non-uniform width constitute acceptable (non-defective) patterns of non-uniformity, such as at location 520 which represents a round pad, may be ascertained on the fly, or by evaluation with reference to an inspection reference produced in an offline learning process which first analyzes a reference that is known to be properly not defective. A suitable reference is, for example, produced from a computer aided manufacturing (CAM) file of the pattern being inspected from an image of a circuit board which is know to be properly formed.

In accordance with an embodiment of the invention, patterns of non-uniform line width in an inspected pattern which occur at a location which does not have a corresponding non-uniform line width in the reference are deemed defects. Moreover, patterns of non-uniform line width in an inspected pattern which occur at the same location as an acceptable pattern of non-uniformity in the reference, but which exhibit a differently configured pattern of non-uniformity from the corresponding non-uniform pattern in the reference, may also be deemed defects, such as at location 518.

In some embodiments of the invention, non-uniformity which is in the form of an increase in line width, such as at a round pad (e.g. location 520) are not recorded in the offline learning process or during inspection, e.g. because they do not meet a requirement of being a reduction in width relative to a preceding segment of uniform width. In such embodiments, only those portions of a conductor in which a line changes from a first uniform relative wide width to a second uniform relatively narrow width are recorded in the learning process and are deemed acceptable patterns of non-uniformity.

In accordance with an embodiment of the invention, in a learning process the locations of actual changes in line width of a conductor segment, from uniform sections of relative wide conductor to relative narrow conductor, are ascertained and stored in memory, and then in a subsequent inspection mode an operator applies an acceptable tolerance range, for example ±n pixels, for determining whether changes in line width are acceptable or potentially not acceptable. Potentially not acceptable changes in line width are checked against the reference to determine whether the change in line width was present in the reference. Changes in line width that were not present in the reference are reported as defects. Moreover, in some embodiments of the invention, during inspection of a circuit board, or other suitable pattern, the actual line width of uniform conductor segments are checked against the line width of corresponding segments in the reference, as automatically calculated from the learn process, to ensure that the actual line width of a uniform segment in an inspected board falls within the acceptable tolerance range.

In other embodiments, the inspection of a board for defects is performed “on the fly” during an automated optical inspection phase. In such embodiments, the presence of a defect may be ascertained be evaluating a change in line width with reference to one or more rules. For example, a not acceptable change in line width may be the presence of a segment of a pattern portion that is narrow when compared two immediately adjacent linear pattern portions that are each generally the same width. A typical application when such “on the fly” evaluation may be employed is in the preparation of a reference image from an actually inspected electrical circuit. When portions of the image appear to be indicative of a nick defect, the image is either discarded from use as a reference, or at least some of those portions indicative of nicks are masked, for example by pixel level manipulation of the image or by ignoring the presence of a nick indication at that location.

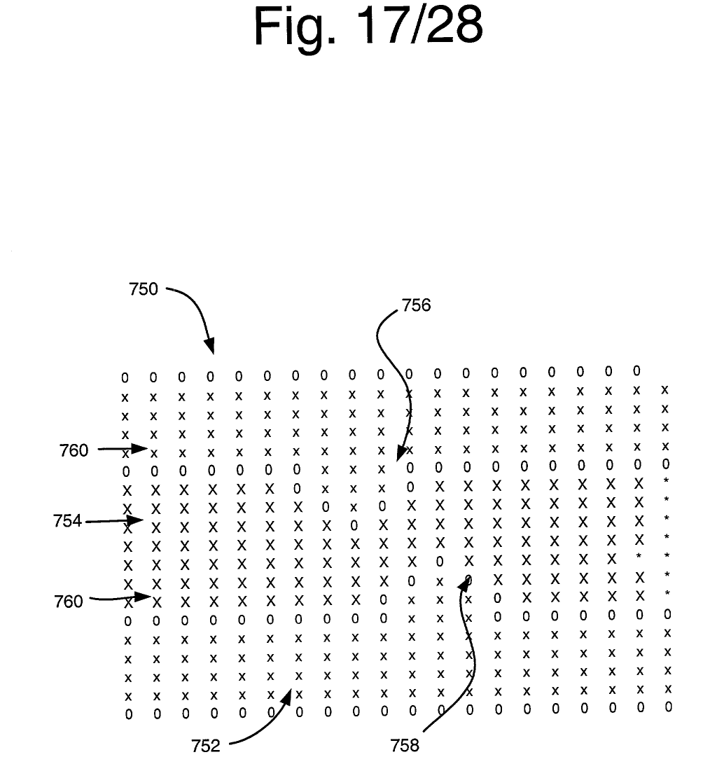

It is noted that the board may be thought of as having conductor areas and non-conductor areas. It is further noted that one kind of defect in a board is an indentation or nick 522 in a conductor, such as is seen in image 504. An indentation in a conductor area may also be thought of as a protrusion in a non-conductor area, and vice-versa. Some shorts between adjacent conductors may be detected by identifying proximally located protrusions in the conductors, for example as described hereinbelow with reference to FIG. 17.

The inspection processing can be applied to conductor areas and non-conductor areas alike, and thus the more general term “board pattern” (or just “pattern”) is used herein. It can mean a part of the circuit board having a conductor or a part of the circuit board having no conductor on it. In general, although the various embodiments of the invention are described herein in the context of a system and methods for inspecting printed circuit boards, it is appreciated that the invention may be applied to any suitable circuit inspection, including without limitation, inspection of semiconductor circuits, ball grid array substrates, multi-chip modules and other suitable electrical circuits and patterns. Any reference herein to board, circuit, circuit board, electrical circuit or pattern shall be considered as being directed to the inspection of any suitable patterned article.

Part of a board pattern may, for the sake of generality, herein be referred to as a board segment, portion, or part.

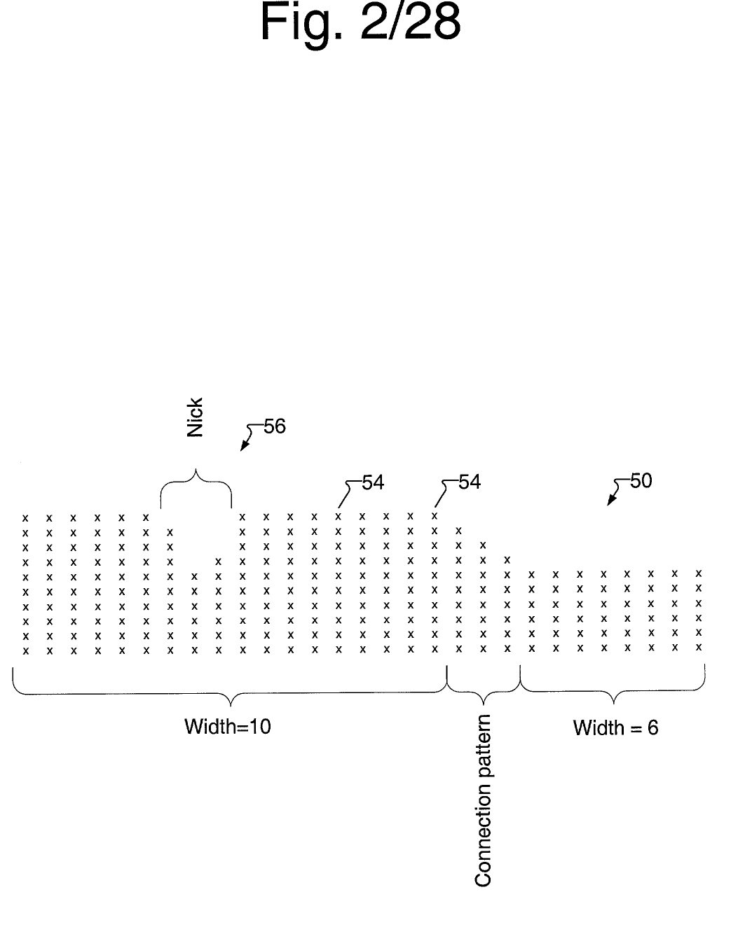

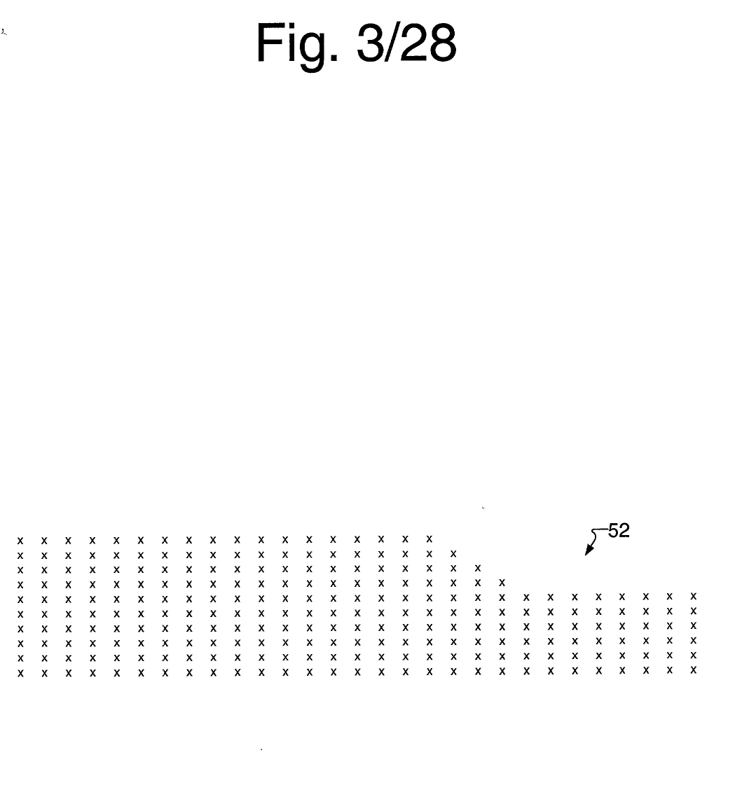

Reference is now made to FIG. 2 which shows a representation of a segment 50 of a board pattern that is imperfectly formed, and to FIG. 3 which shows a corresponding representation of segment 52 shown in FIG. 2, but which is perfectly formed. The representations 50 and 52 are shown using individual pixels 54 defining an image, similar to image 504 in FIG. 1, but of a different segment, of the pattern obtained by imaging the circuit board 16 under inspection. A first part of the pattern has a width of 10 units (units may be, e.g., pixels in a digital image as in this example or any other suitable unit of measurement) in FIGS. 2 and 3, but FIG. 2 shows a nick 56. A second part of the pattern has a width of 6 units. Between the first part of the pattern and the second is a transition part, which may be thought of as a connection pattern. It will be appreciated that the first part of the pattern has the same width, and extends to the left of the figure, and that the second part of the pattern extends to the right.

A conventional inspection apparatus typically inspects for one or more globally applied width dimensions, although it can handle tolerances. That is, for example, during a given inspection, a conventional inspection apparatus could be set to check that portions of patterns have a width of 10 units, plus or minus 1 (i.e., a width of 9 to 11 units). Additionally, a conventional inspection apparatus could be set so as conveniently to check whether portions of patterns have a width of 6 units, plus or minus 1 unit (i.e. a width of 5 to 7 units). All non-defective portions of the pattern will fall within one or the other of the above acceptable width ranges, while portions which are outside either of the ranges are deemed defective. It is noted that, because the above two exemplary ranges of acceptable widths do not overlap, it is possible to readily determine whether a conductor is or is not defective for any width obtained during an inspection process.

Uncertainty can arise, however, if a conventional inspection apparatus is set so that it checks for patterns having acceptable width ranges which adjoin, or which overlap. For example, assume that one width range is defined as 10 units, plus or minus 2 units (i.e., a width of 8 to 12 units). Assume another width range is defined as 6 units plus or minus 2 units (i.e., a width of 4 to 8 units). With adjoining or overlapping width ranges, an uncertainty arises as to whether a conductor is or is not defective whenever a conductor width is found to be in the area intermediate the two acceptable widths. A conductor location found to be 7 units wide may, in the example given, be a defectively narrow conductor of nominally permissible width 10, or it may be an acceptably wide conductor of nominally permissible width 6. Likewise, a conductor location found to be 8 units wide may, in the example given, be a either an acceptable wide conductor of nominally permissible width 6 or an acceptably narrow conductor of nominally permissible width 10.

To provide a system that detects nicks but does not incorrectly flag perfectly (or at least well enough) formed patterns, the embodiments described herein employ local width information, which may be considered as being proximal width information. This will now be explained in more detail.

Patterns in typical printed circuit boards typically include substantially linear portions. According to the present embodiment, a pattern is inspected not with respect to one or more universal, or globally applied, pattern width dimensions but, rather, with respect to the respective widths of proximal locations along a pattern being inspected.

In a first step, a given pattern on the board is selected for inspection, such as the representation of segment 52 shown in FIG. 3.

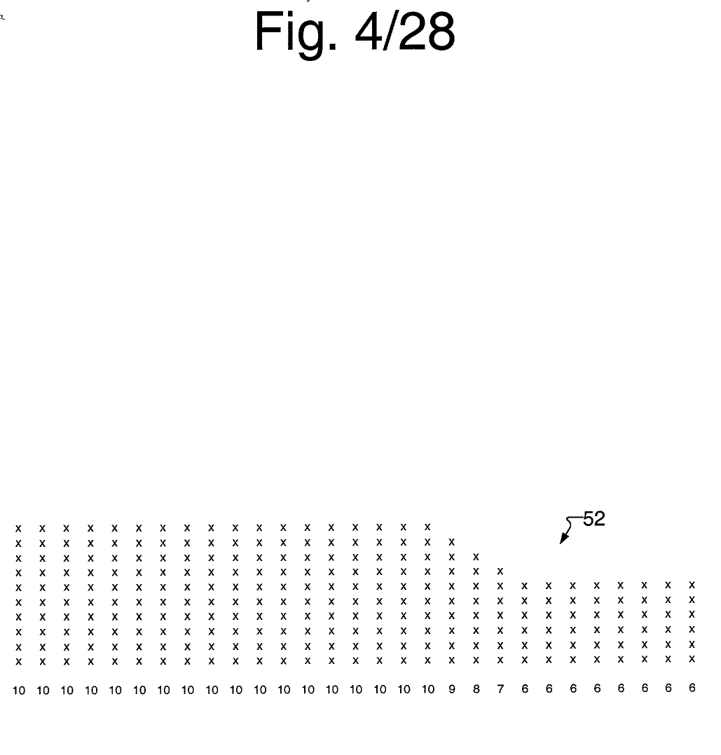

Next, the width along the pattern is determined at selected locations, as shown in FIG. 4, preferably in an isotropic manner to insure the same results regardless of the planar orientation of the pattern. It is noted that in FIG. 4 all possible locations in the image are selected to show the width, although a lesser set of locations may also be selected.

After determining the width, the pattern is analyzed to make defect determinations.

One way to perform this analysis is to identify vectors (i.e., parts of the pattern having a substantially uniform width over a length exceeding a predetermined threshold) and non-vectors. Here, “substantially uniform width” means a width that does not vary beyond an acceptable tolerance. Also, having this substantially uniform width over a length exceeding a threshold means that this width is maintained for at least a given distance.

One way to set the predetermined vector length threshold is to pick a length based on various intuitive factors, given a general knowledge of the type of board being produced. Another way to pick the predetermined vector length threshold is to set it so that a vector length must be at least as long (or longer by n units) than its width. In other words, for a part of a pattern that has a width of 6 units, the determination of the existence of a vector requires that the width of 6 units be substantially the same for at least 7 or more units in length. This ensures that, in accordance with some embodiments of the invention, only rectangular pattern portions are defined as vectors.

For the sake of simplicity of explanation, in the examples presented herein, and unless otherwise indicated, the predetermined vector length threshold will be 5 units and the tolerance for determining a segment to be a vector will be plus or minus 1 unit.

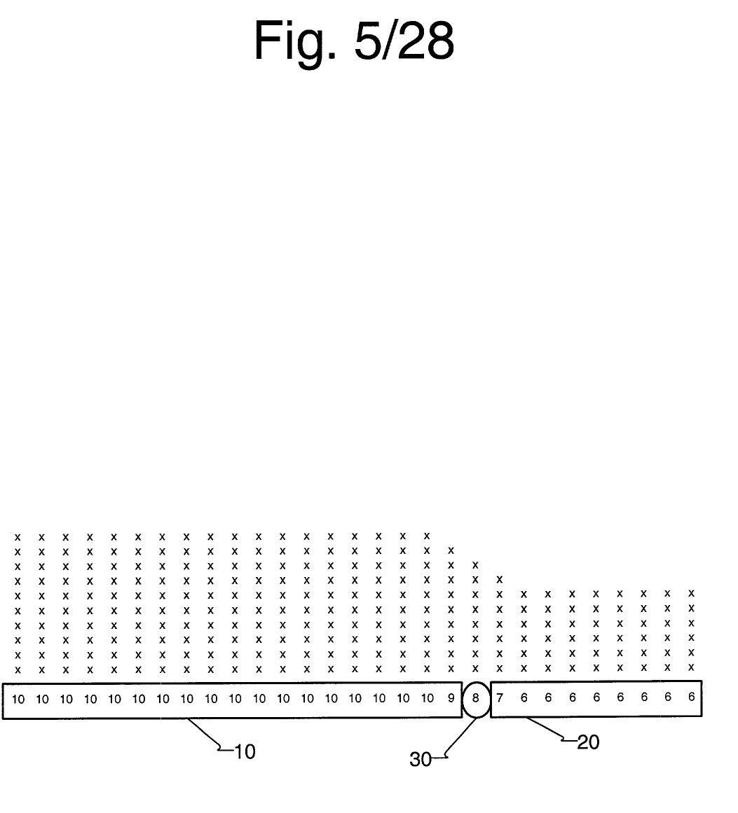

Vector identification is shown in FIG. 5. In FIG. 5, a first vector designated reference numeral 10 and a second vector designated reference numeral 20 are shown. The first vector 10 has a width of 10 units along most of its length, except at the end where its width is only 9 units. The part where the width is only 9 units is included in the first vector 10 because this varies from the rest of the vector by only plus or minus 1 unit. The second vector 20 has a width of 6 units along most of its length, except that the beginning part has a width of 7 units, which is within the predefined tolerance of 1 unit.

In addition to the identification of vector portions, a non-vector portion is identified as well. Reference numeral 30 indicates a non vector portion in between the first vector 10 and the second vector 20. The vector portions are usually of no great concern, but events occurring at the ends of vector portions, and in some embodiments of the invention non vector portions, are worthy of further analysis.

It is noted however that in some embodiments of the invention the vector portions may be checked against a stored line width value in order to ensure that, although uniform, the vector width does not fall outside an acceptable range of values. One way to quickly and easily perform such a check is to record the values of selected vector portions in a pattern. If one or more of selected the vector portions falls outside an acceptable tolerance range, a general defect, such as over etching or under etching of conductor regions on a circuit board, may be indicated, and remedial measures in manufacturing processes may be required to remedy the defect.

After the width identification step, the non vector portions are analyzed. The analysis is based at least on proximal width information, and also may be based on one or more rules. In accordance with an embodiment, presently described, a non vector portion is indicated as a defect only when:

it is shorter than the predetermined vector length threshold (a rule), and

it is a nick exceeding a predetermined threshold occurring immediately at the beginning or end of a vector (proximal width information).

Other rules may be applied. For example, an additional rule may be that the slope of a non-vector portion exceeds a predetermined value. Still an additional rule may be that the non-vector portion is both preceded and followed by a vector portion of the same width. The above rules are intended to be non-limiting. The proximal width information need not necessarily include both sides of the non vector portion even though it does for the present embodiment of the invention.

In FIG. 5, the non-vector portion 30 exceeds a non-uniformity width threshold (1 unit) and is shorter than the predetermined vector length threshold (5 units), so it could qualify as a nick type defect. In accordance with some embodiments of the invention, because the non-vector portion is located immediately at the end of vector 10, it would be recorded in a learning process. In the subsequent inspection of a pattern, detection of the non-vector portion 30 would be ignored whenever a similarly located “nick” is detected in the inspected image. It is appreciated that if, in an inspection mode, an actual nick in an inspected image is detected between non-vector portion 30 and the following vector portion 20, then an additional non-vector portion (not shown) would be detected (that is to say two non-vector portions being detected in the vicinity of non-vector portion 30). The in the absence of a corresponding non-vector portion in the reference the second non-vector portion would be reported as a defect.

In accordance with other embodiments of the invention, it is noted that the non vector portion 30 is preceded by a vector having a width of 10 and is succeeded by a vector having a width of 6. Thus, in accordance with some rules, it is no defect indication should be given for the non vector portion 30.

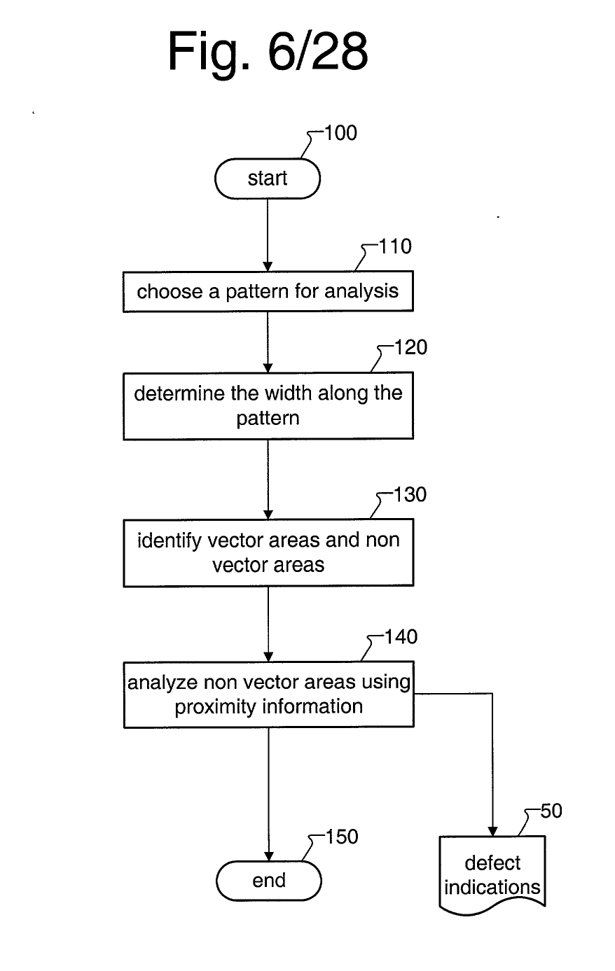

Reference is now made to FIG. 6 which is a flow diagram of an inspection method in accordance with an embodiment of the invention. The foregoing steps will now be described in terms of the flow diagram shown in FIG. 6.

In FIG. 6, processing begins with step 100. A pattern (such as 506 in FIG. 1) is chosen for analysis in step 110. The width measurement along the pattern is performed in step 120. The vector identification is performed at step 130. Analysis of the non vector portions is performed in step 140, and the analysis is based on the proximal width information and orientation of the non-vector areas relative to vector areas. Any defect indications 506 are output in a report 50, and processing concludes at step 150.

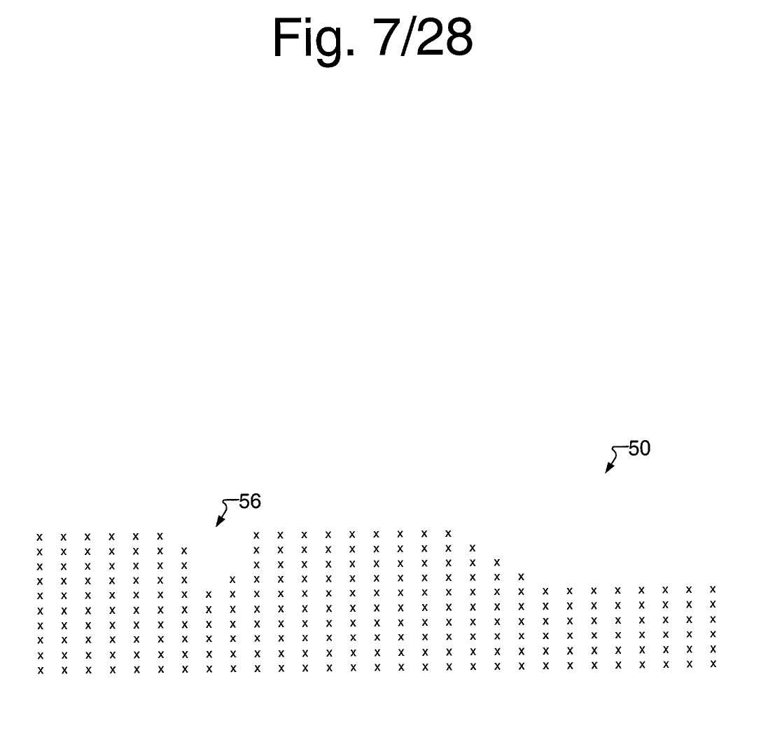

Reference is now made to FIG. 7 which is a segment 50 of a defective conductor portion in pattern, such as on circuit board 16. The processing employed in the method shown in FIG. 6 will now be described with reference to the pattern shown in FIG. 7. Segment 50 in FIG. 7 is the pattern selected in the pattern choosing step 110. Segment 50 contains a nick 56.

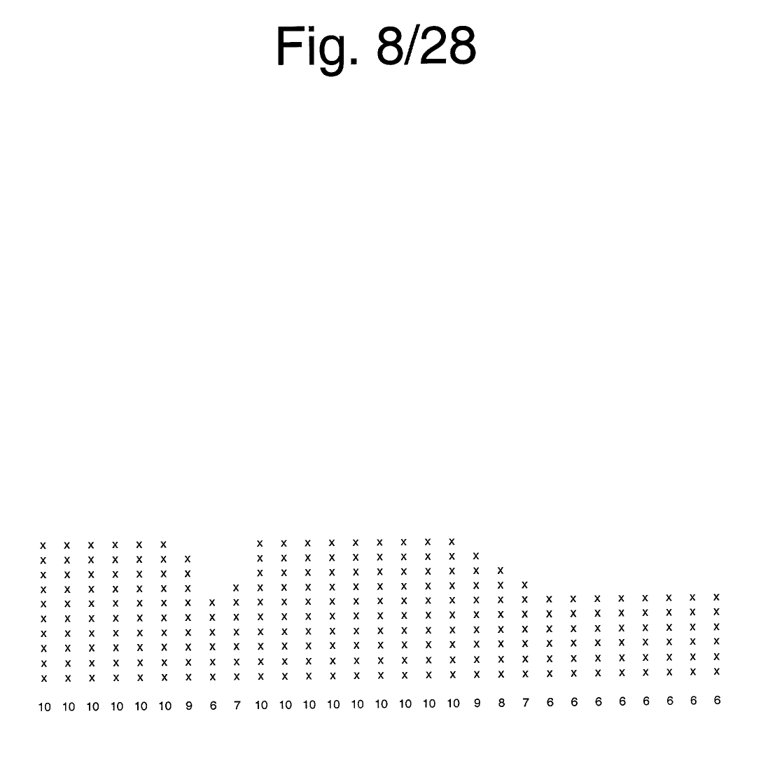

The width measurement is performed with respect to this pattern in step 120, as shown in FIG. 8.

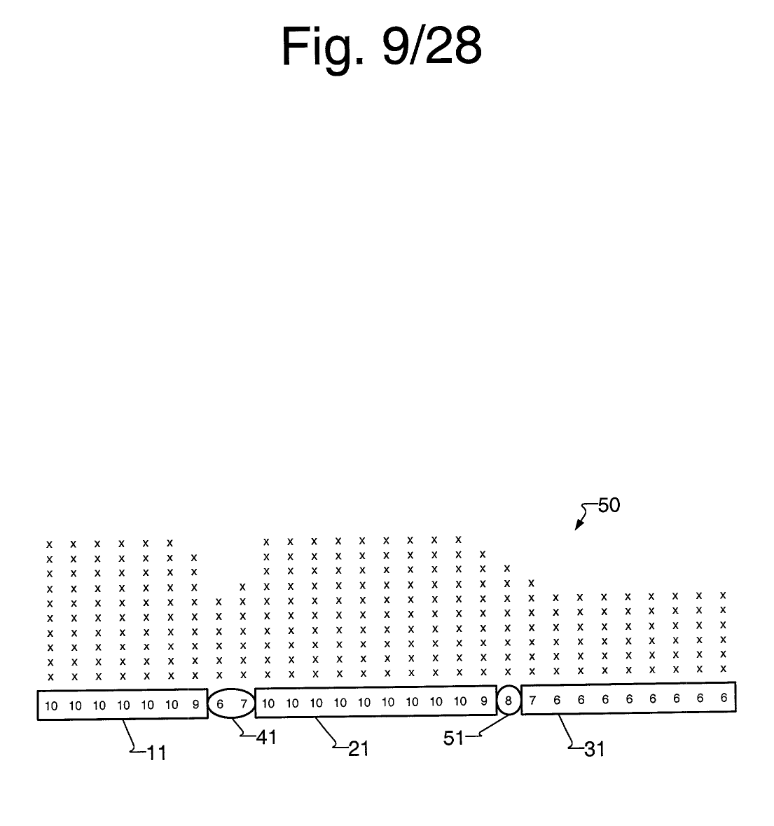

The vector identification of step 130 is performed, and the results are shown in FIG. 9, in which vectors 11, 21, and 31 have been identified. Non vector portions 41 and 51 also have been identified.

Each non vector portion 41 and 51 is then analyzed in relation to adjoining vectors 11, 21 and 31. The difference in width between non-vector portion 41 and either of its adjacent vector portions 11 and 21 exceeds the predetermined threshold. Moreover the length of non vector portion 41 is less than the predetermined vector length threshold. Because no corresponding non-vector portion is found in a reference created from conductor 52 (FIGS. 4 and 5), non-vector portion 41 is indicated as a defect.

Alternatively, a rules based analysis may be carried out. Assume that the rules include a requirement that any non-vector portion which is preceded and succeeded by a vector portion of the same width be deemed a defect. Non vector portion 41 is preceded by a vector that can be said to have a width of 10 units. Non vector portion 41 is succeeded by another vector having a width of 10 units. Therefore, non vector portion 41 is determined, in accordance with the above indicated rule, to be a defect and a defect indication 50 is generated for this part of the board.

Regarding non vector portion 51, although it exceeds the width difference threshold and is less than the predetermined vector length threshold, because it has a corresponding non-vector portion 30 (FIG. 5) of a conductor known to be properly formed, as ascertained in a previous learning process, it is not deemed a nick.

Alternatively, by applying the alternative rule noted above, because non-vector portion 51 is not preceded and succeeded by vectors having generally the same width, no defect indication is generated for non vector portion 51.

The detection of vector and non vector portions is one way to analyze proximal width information for the purpose of making a defect determination.

By basing the defect determination on proximal width information instead of a universal predetermined width, it is possible to inspect patterns having various widths, and, in accordance with some embodiments of the invention, still detect defects, even “on the fly”. Moreover, it is possible to inspect conductors that have a changing width, such as wedge shaped conductors having edges that slope toward each other.

In another embodiment, a simplified computational process optimizing the use of computational hardware resources simplifies the identification of vector portions and the analysis of non vector portions.

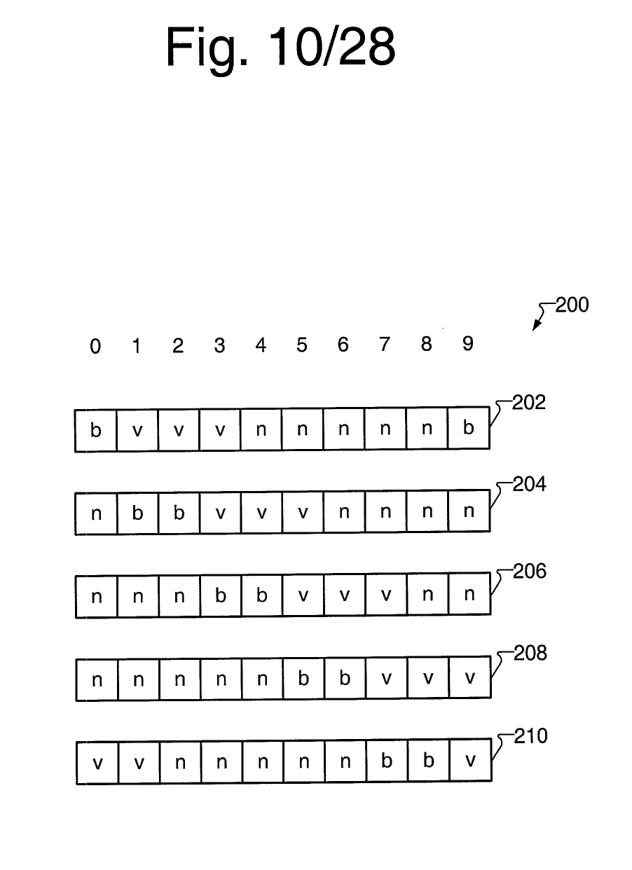

Reference is made to FIG. 10 which shows a look-up table (LUT) 200 used in an embodiment of the invention operative to determine pattern width in a simplified computational process. The LUT includes a plurality of different rows identified by reference numerals 202, 204, 206, 208, and 210, respectively.

In accordance with an embodiment of the invention, it is appreciated that the width of a conductor is not known ahead of time, and that uniformity of width needs to be evaluated in an entirely relativistic manner without necessarily knowing the width. Thus each row in the LUT 200 is operative to identify whether a pattern portion is a vector, while taking into account an acceptable tolerance, for a different width. In the embodiment represented by LUT 200, when sequential width data for a segment is applied to LUT 200 each row therein indicates whether the segment is or is not a vector of a predetermined width associated with that row.

When evaluating a conductor segment of previously unknown but generally uniform width using LUT 200, the result is that the segment is indicated by at least one row as a vector associated with that row, while other rows indicate that the segment is not a vector associated with that row. It is appreciated that when analyzed with LUT 200, a conductor segment of generally uniform width will appear as a vector in one or possibly two of the rows of LUT 200, while in the other rows of LUT the segment of generally uniform width will appear as being not a vector.

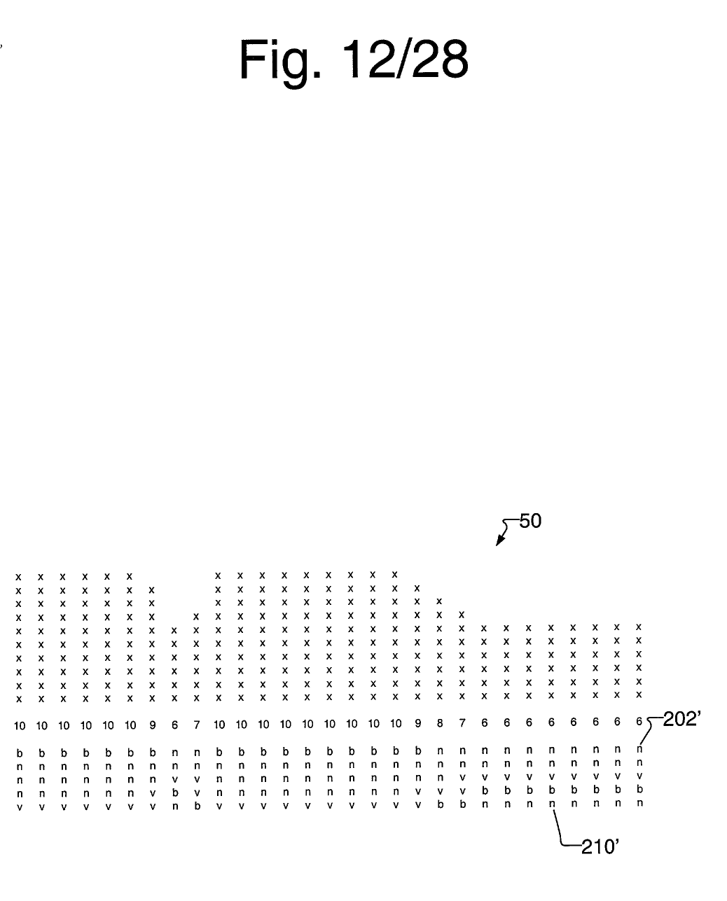

In the embodiment of LUT 200 seen in FIG. 12, there are ten columns, numbered above, for convenience, with digits 0-9. Each column relates to a possible number of pixels, or width units, in a conductor segment. Row 202 is designed for identifying vectors having a generally uniform (±1 unit) width of either 2 units, 12 units, 22 units, and so on. It is appreciated that a conductor cannot be at the same time two different widths. Thus, in an abbreviated manner, LUT 200 may be applied cyclically.

In row 202, the symbol “v” for vector appears in the columns 1, 2, and 3. This is because the intended vector width to be detected by row 202 is 2 pixel units, plus or minus one pixel. Hence, “v” is at column 2. Additional “v” indicators are also at columns 1 and 3 corresponding to an acceptable tolerance.

Also in row 202, the symbol “b” for bridge appears in the two columns, 0 and 9, which are to the left of column 1, assuming that the columns wrap around. The concept of the bridge is that of a connecting pattern, such as is shown above in FIG. 2. The number of columns given to bridge symbols corresponds to a maximum slope permissible between a vector and a nick, and is determined as a function of operator judgment.

The remaining symbols in row 202 are “n” corresponding to an unacceptable with reference to a vector section, such as is characteristic of a nick (or other defective indentation).

Row 204 is designed for vectors of a width of 4 units (and also 14 units, 24 units, etc.), and is otherwise similar in structure to row 202. In like manner, row 206 is designed for vectors of width 6 (16, 26, etc.); row 208 for vectors of width 8 (18, 28, etc.); and row 210 for width 10 (20, 30, etc.).

It is appreciated that additional rows may be interleaved into LUT 200 in order to accommodate conductors of other nominal widths, for example 1,3,5,7 and 9 units wide. Additional rows may be added to LUT 200 accommodate even wider width conductors, without having to use each of rows 202-210 to each handle several possible widths.

Moreover, a LUT may be implemented in FPGA type hardware units, or other suitable hardware, such that various LUTs, each similar to LUT 200, may be selectively loaded in order to accommodate different width conductors. Thus, in some embodiments of the invention, for example during a learning process, different LUTs are sequentially loaded into a hardware processor having the capacity to accommodate LUT 200. Each LUT ascertains the presence of conductors in a different width range, and a circuit board to be processed is analyzed using each of the different LUTs so that defects may be detected on a full range of conductor widths.

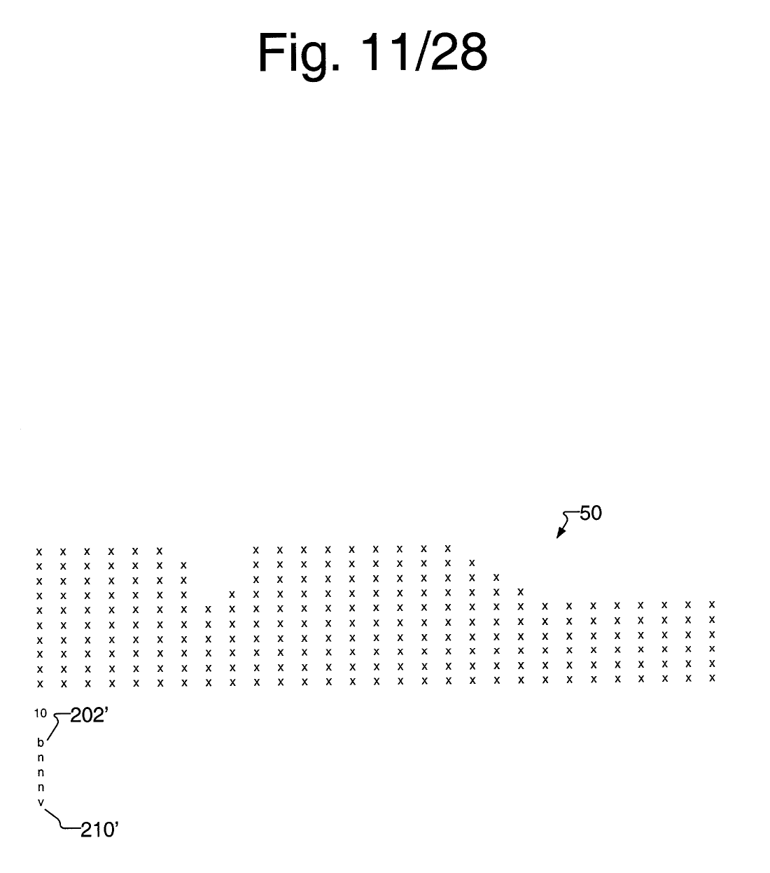

The use of the LUT will now be illustrated with reference to segment 50 of FIG. 9, as reproduced in FIG. 11.

In FIG. 11, the width of the leftmost part of the pattern has been determined to be 10 units. The determination of the width may be made, e.g., using erosion or dilation processes, such as are employed in the V-300™ and INSPIRE™ automated optical inspection systems available from Orbotech of Yavne, Israel, or by any other suitable width detection and methods. This width is mapped to a corresponding column in the LUT 200, using modulo division or the like. The column in the LUT 200 corresponding to the width of 10 units is column 0. A width of 1 or 11 units (or 21, etc.), due to the repetitive nature of LUT 200, would correspond to column 1, and so on.

In LUT 200, the corresponding values from column 0 are found for each row 202-210, and are recorded with respect to the part of the pattern being analyzed. In FIG. 11, 202′ indicates the value in the LUT 200 found from row 202, and 210′ indicates the value found from row 210. The values in between came from rows 204, 206, and 208, respectively.

It can be seen that the values “b”, “n”, “n”, “n”, and “v” were found from column 0 of rows 202, 204, 206, 208, and 210, respectively. The particular letters are of no special significance, and numbers or any other suitable indicators could be used, as appreciated by one familiar with this field will appreciate. For generality, therefore, these values may be hereinafter referred to as width indicia.

FIG. 12 shows the width indicia generated for the entire pattern of segment 50. For the sake of convenience, the row of width indicia generated from rows 202-210 (and indicated by 202′-210′ respectively) may be thought of as processing channels. With the LUT 200 shown in FIG. 10, therefore, it can be said that five different processing channels are applied, and each generates a representative width indicia for corresponding parts of a board pattern.

For convenience as well, the channel generated from row 202 will be referred to as a first channel 212, from row 204 as a second channel 214, and so on through row 210 as a fifth channel 220.

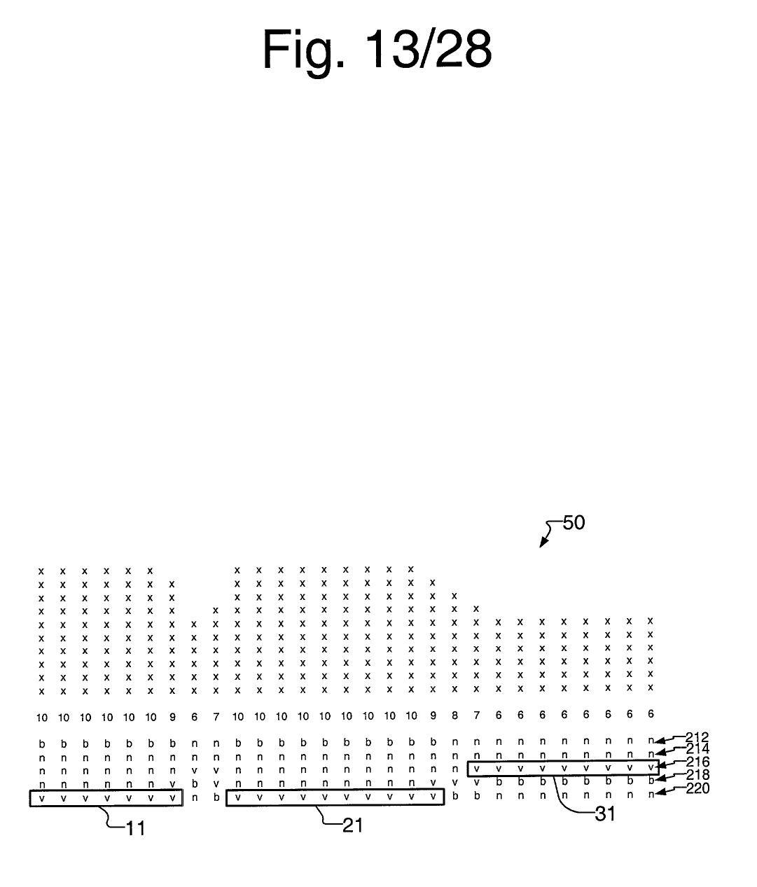

Identification of vector portions is shown in FIG. 13. The identification of vector portions is simple, because any string of 5 “v” width indicia (recall that the arbitrarily predetermined vector length threshold in these examples is 5 units) in any channel 212-220 indicates the presence of a vector in the corresponding portion of segment 50.

In FIG. 13, there is a first vector 11 indicated in fifth channel 220, and a second vector 21 also indicated in fifth channel 220. First vector 11 and second vector 21 correspond to pattern portion having a nominal width of 10 units, with portions thereof being 9 units in width (which is an acceptable deviation from the generally uniform nominal width of 10 units). It is appreciated that when using an abbreviated LUT, such as LUT 200, the width first vector 11 and vector 21 may actually be 0, 20, 30 or larger widths in quantums of 10. It is assumed that a conductor width will not change by exactly 10 units, and the actual width however is not of consequence insofar as it remains uniform.

A third vector 31 is indicated in third channel 216. Third vector 31 corresponds to a pattern portion having a nominal width of 6 units (or 16 or 26 . . . units), with a portion thereof being 7 units in width (which is an acceptable deviation from the generally uniform nominal width of 6 units).

The non vector portion between vector 11 and vector 21 has a length of 2, which is less than the predetermined vector length threshold. Moreover, the non vector portion has width indicia indicative of a possibly defect width (i.e., “n” for nick), namely a difference in width of at least two as compared to an adjacent vectors 11. Therefore, the non vector portion between vector 11 and vector 21 may be flagged with a defect indication.

The non vector portion between vector 21 and vector 31 has a length shorter than the predetermined vector length threshold. With respect to vector 21, a “b”, indicating a bridge, is found in channel 220 at the location immediately following vector 21. This is not indicative of a nick or defect. However with respect to channel 216, an “n”, indicative of a nick, immediately precedes vector 31.

In accordance with some embodiments of the invention, such an indication would be indicative of a nick but for a corresponding nick indication at a corresponding location in the reference. In accordance with other embodiments of the invention, because vectors 21 and 31 are not in the same channel, indicating that the conductor changes its width between the adjacent vectors, the non-vector portion between vectors 21 and 31 is not indicative of a nick defect. Thus, in accordance with an embodiment of the invention employing the rules stated above, the non vector portion between vector 21 and vector 31 is not indicated as a defect but, rather, is characteristic e.g., of a change of conductor width.

In some embodiments of the invention the slope of the portion connecting vector portions 21 and 31 may be evaluated. For example, it is seen that “b” width indicia appear between vector portions only in channel 220. The quantity of “b” width indicia appearing between two adjacent vectors of different widths may be ascertained and used to determine whether the connection portion has an acceptable slope.

By using a LUT as shown in FIG. 10, which embodies a tolerance (by virtue of the number of “v” indicators) and slope information (by virtue of the number of “b” indicators), and by processing width information in a plurality of processing channels, a simple and efficient method of generating width indicia is realized.

In accordance with yet another embodiment, the appropriate values taken from LUT 200 (FIG. 10) are recorded on the fly. Here, a morphology process is used to generate the width indicia. Morphology processes are well known, but an erosion (or reduction) process will now be illustrated in brief for the sake of clarity. The width of a conductor location is evaluated at each step of a morphological erosion, and the width indicia are recorded immediately.

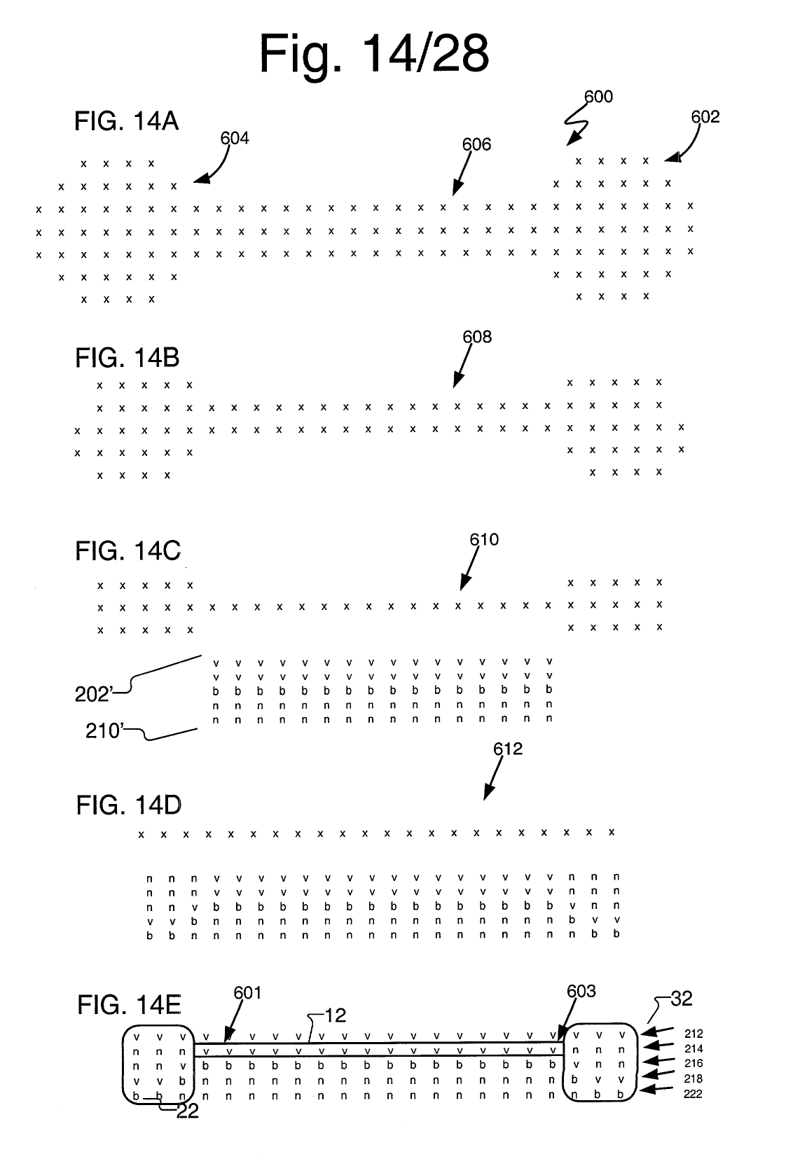

Reference is made to FIGS. 14A to 14E, which show erosion of an image 600 of a conductor section, and recordation of its corresponding width indicia at selected locations. FIGS. 14A to 14E illustrate a generally isotropic erosion. It is appreciated that in actuality the actual pixels which are eroded, and the sequence in which they are eroded, may slightly differ from that shown.

The image 600 of a pattern portion under consideration is shown in FIG. 14A in its unreduced state. The pattern portion includes two round pads 602 and 604 connected by a conductor portion 606.

FIG. 14B shows a first partially eroded image 608 once a first erosion step has been completed, namely once one pixel has been eroded from the top of image 600. It is noted that no portions of image 600 are yet skeletonized, namely the state in which the image portion is completely eroded (i.e., just one pixel remains or no more pixels remain).

In the first partially eroded image 608, the width at each portion is at least 2. This width value is stored and accumulated during each subsequent erosion operation.

For parts of the exemplary pattern that have not been completely eroded (the entire pattern at this point), the final width is not yet determined and width indicia are not yet assigned. The number of pixels already eroded for each part of the pattern is stored, however, so that an overall width determination can eventually be made.

In FIG. 14C, a second eroded image 610 is shown. Second eroded image 610 differs from first eroded image in that an additional set of pixels, predominately one from the bottom side of image 610. That is to say, another erosion cycle has taken place. In this figure, the extreme left and right parts of pads 602 and 604 have been completely eroded, and the conductor portion 606 has been skeletonized to a single pixel width. At this point, the width value for conductor portion 606 is applied to the LUT 200 shown, e.g., in FIG. 10.

In FIG. 14C, 202′ indicates the value for a width of 3 pixels found in the LUT 250 from row 202, and 210′ indicates the value for a width of 3 pixels from row 210. The values in between came from rows 204, 206, and 208, respectively (see FIG. 10). In accordance with some embodiments of the invention, the extreme pixels in channels 202′ and 204′ may indicated as extreme pixels in a vector. This provides an instruction not to check for nicks before or after the extreme pixels, respectively, since “n” pixels resulting from subsequent stages of erosion would be indicative of a widening of the conductor, and not of a nick in a vector.

For second eroded image 610, width indicia are shown only for those portions that have been skeletonized.

The erosion procedure is continued and a third eroded image 612, in which pixels in the region of pads 602 and 604 are removed. As seen in Fig. The isotropic nature of erosion results in an extension of the skeleton corresponding to conductor portion 606.

In FIG. 14E, erosion results in 600 becoming completely eroded. The location of a vector, appearing in both channels 202′ and 204′ is shown.

In FIGS. 14C-14E, strings of width indicia for each processing channel are carried from stage to stage of erosion until image 600 becomes fully skeletonized. In FIG. 14D additional width indicia are provided for the additional location whereat image pads 602 and 604 become skeletonized. Each processing channel thus provides a corresponding string (or series) of width indicia (5 strings in the embodiment being described here).

Each processing channel provides a one dimensional representation, in a respective string of width indicia, of a two dimensional pattern. Together, the strings of width indicia may be thought of as an indicia set, and constitute a plurality of one dimensional symbolic representations of the corresponding pattern of the circuit board.

The pattern of 14A, when skeletonized to the point shown in 14D (i.e., completely eroded), may replaced with a one dimensional string of width indicia.

FIG. 14E also shows the identification of vector portions. Reference numeral 12 indicates a vector portion located in channel 214, that can be identified from among the sets of width indicia for each of channels 212-220. Non-vector portions 22 and 32 are identified as well.

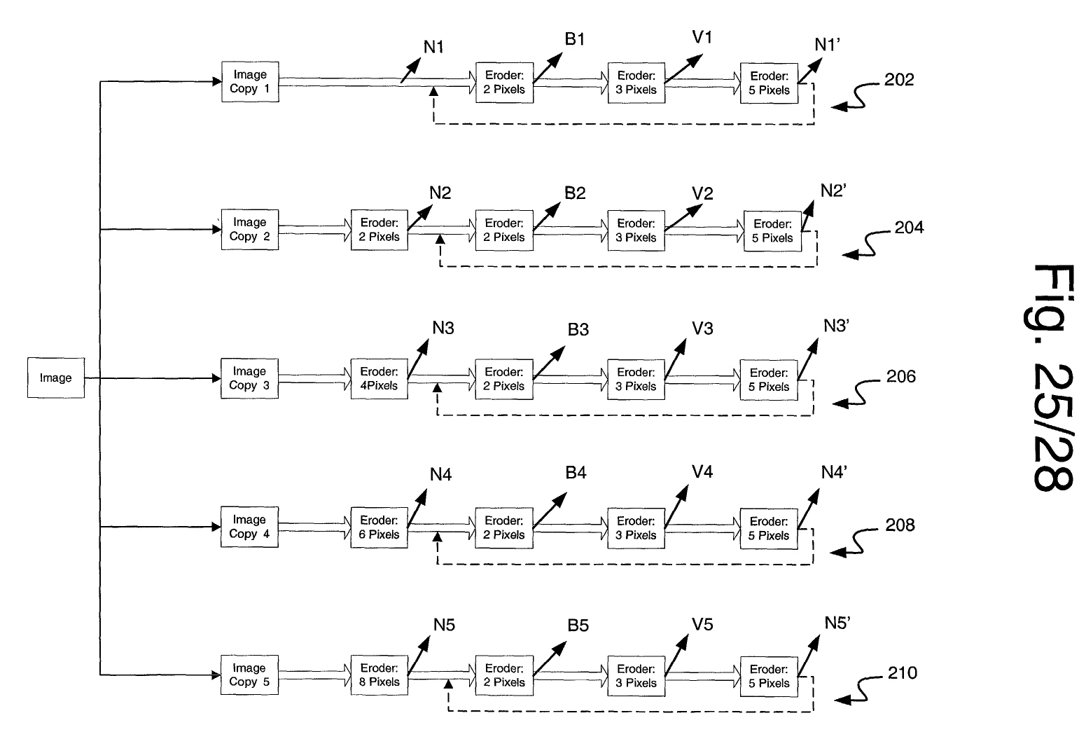

Reference is now made to FIG. 25 which is a schematic drawing of hardware employed in the implementation of LUT 200 in a preferred mode of operation. An image of the pattern to be inspected is copied into image copy 1, image copy 2, image copy 3, image copy 4 and image copy 5 respectively. The image may be an image of a complete pattern, or of one or more predetermined selected portions of a pattern. Each of the image copies are supplied to one of channels 202-210, which typically are separate hardware processors, each of which operates simultaneously on a respective image copy.

In channel 202, image copy 1 is evaluated to determine any portions that have been skeletonized, namely reduced to a width of 0 or 1 pixels, and an indication of “N” is recorded for channel 202 at each of the skeletonized portions. Image copy 1 is then supplied to a first eroder circuit which erodes the pattern by 2 pixels. Following erosion by 2 pixels, image copy 1 is once again evaluated to determine any portions that have been skeletonized, and an indication of “B” is recorded for channel 202 at each of the additionally skeletonized portions. Image copy 1 is then supplied to a second eroder circuit which erodes the pattern by an additional 3 pixels. Following erosion by an additional 3 pixels, image copy 1 is once again evaluated to determine any portions that have been additionally skeletonized, and an indication of “V” is recorded for channel 202 at each of the additional skeletonized portions. Image copy 1 is then supplied to a third eroder circuit which erodes the pattern by an additional 5 pixels. Following erosion by an additional 5 pixels, image copy 1 is once again evaluated to determine any portions that have been additionally skeletonized, and an indication of “N” is recorded for channel 202 at each of the additional skeletonized portions.

In channel 204, image copy 2 is first provided to an initial eroder operative initially to erode image copy 2 by 2 pixels. Image copy 2 is then evaluated to determine any portions that have been skeletonized, namely reduced to a width of 0 or 1 pixels, after initial erosion, and an indication of “N” is recorded for channel 204 at each of the skeletonized portions. Image copy 2 is then supplied to a first eroder circuit which erodes the pattern by an additional 2 pixels. Following erosion by an additional 2 pixels, image copy 2 is once again evaluated to determine any portions that have been additionally skeletonized, and an indication of “B” is recorded for channel 204 at each of the additional skeletonized portions. Image copy 2 is then supplied to a second eroder circuit which erodes the pattern by an additional 3 pixels. Following erosion by an additional 3 pixels, image copy 2 is once again evaluated to determine any portions that have been additionally skeletonized, and an indication of “V” is recorded for channel 204 at each of the additional skeletonized portions. Image copy 2 is then supplied to a third eroder circuit which erodes the pattern by an additional 5 pixels. Following erosion by an additional 5 pixels, image copy 2 is once again evaluated to determine any portions that have been additionally skeletonized, and an indication of “N” is recorded for channel 204 at each of the additional skeletonized portions.

In various embodiments of the invention, the same process also occurs simultaneously in each of channels 206, 208, and 210, except that the image copy is initially eroded by 4, 6 and 8 pixels prior to the initial evaluation of which portions of the images, image copy 3, image copy 4 and image copy 5 are skeletonized after the initial erosions

In the event that, following erosion by the third erosion processor in any of channels 202-210, there remain portions of the image which are not fully eroded, the respective image copies 1-5 are provided sequentially to the first, second and third erosion processor, in a looping manner, for further erosion until all of the images are fully eroded. Each of the erosion processors may be discrete hardware processing units, or alternatively they may be a single hardware processing unit, such as an FPGA, which receives a instruction prior to each erosion step. Moreover, changes to the LUT 200, for example to reflect a larger permitted variation in the width of a Vector or of a Bridge, may be readily implemented by changing the number erosion steps performed by each of the respective first second and third erosion processors.

In various embodiments of the invention, therefore, the defect determination is based on an analysis of proximal width information, e.g., by considering whether an image of a conductor is generally uniform over a predetermined length. The analysis includes determination of vector portions and non vector portions. The pattern of non vector portions, namely pattern sections of non-uniform width, and/or the spatial relationship of non-vector portions to vector portions, are considered to determine whether a non-vector portions are representative of a defect or of an acceptable non-uniformly wide section of a pattern. Such acceptable non-uniformly wide sections include, for example, bridge portions, pads, corners and the like. It is noted that the width information relating to a board pattern is obtained through a morphological process.

Yet one more embodiment of the invention involves the classification of non vector portions. It is appreciated (for example by observation of non-vector portion 22 and non-vector portion 32) that various conductor portions may have characteristic width indicia patterns. Thus, for example, it is seen that non-vector portions 22 and 32 respectively, which are perfectly formed pads at the end of a straight conductor portion, are in fact mirror images of each other. In the indicia set, the symbols belonging to non vector portion 22 may be thought of as an indicia subset related to the round pad. Likewise, the symbols belonging to non vector portion 32 are an indicia subset. In accordance with some embodiments of the invention, the indicia patterns can be represented in various ways, and stored in an indicia pattern dictionary for use in classifying non vector portions.

It will be appreciated that non vector portions of many types, for example corners, connecting portions of too gradual or too steep slope, balls in a ball grid array and the like, can be included in a dictionary of non-vector portions, and not just round pads. Furthermore, the indicia pattern need not be a pattern of just or only one particular symbol. The “v” symbol was used here with respect to round pads, but any combination of any symbols that is distinctive can be included in the indicia pattern dictionary.

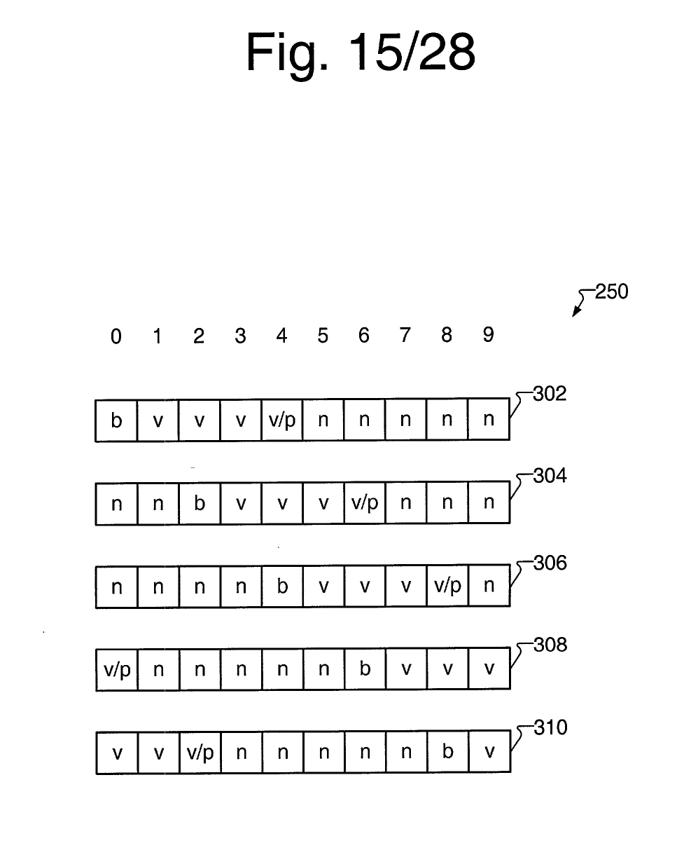

In yet even another embodiment a modified LUT 250 is used, as shown in FIG. 15. The modified LUT includes width indicia for indicating the termination of a vector under predetermined circumstances. Due to the cyclical nature of LUT 200, and its wrap around implementation, under some circumstances nicks may be indicated both for portions at which a conductor exhibits a restricted width (a real nick) as well as where conductor width increases (for example at a connection portion as seen in FIG. 2). Therefore, in order to ensure that a nick is indicated only where the width of a non-vector segment is actually less than its neighboring vector segment, a termination indicia may be applied where a subsequent location along a pattern is wider than a preceding vector. Such an indicia provides an instruction not to consider any subsequent “lnick” indications as being a nick with respect to the preceding vector segment.

In FIG. 15, reference numeral 302 indicates a row corresponding substantially to row 202 of the LUT 200 shown in FIG. 10, except that the bridge indicia have been reduced, and a “v/p” (vector and possible terminator) indicia has been added. The “v/p” indicator, when present, is subjected to a subsequent, additional analysis to determine whether the part should be marked “v” or “p”. The selection depends on the arrangement of the skeleton at the time the indicator is generated.

Referring back to FIG. 14, it is seen that in accordance with an embodiment of the invention the “v” width indicia 601 and 603 at either end along vector 12 may be indicated as being terminating a vector “v/p”. This is because pad portions 602 and 604 are wider than conductor portion 606. Because portions 602 and 604 are wider, even though they show “n” width indicia, they can not be considered nicks because of their increased width relative to conductor portion 606. By applying a vector terminating indicia, an instruction is given to look for nicks on vector 12 only between the terminating indicia, and to signify that a subsequent nick indication does not indicate a nick on conductor portion 606 but a widening thereof.

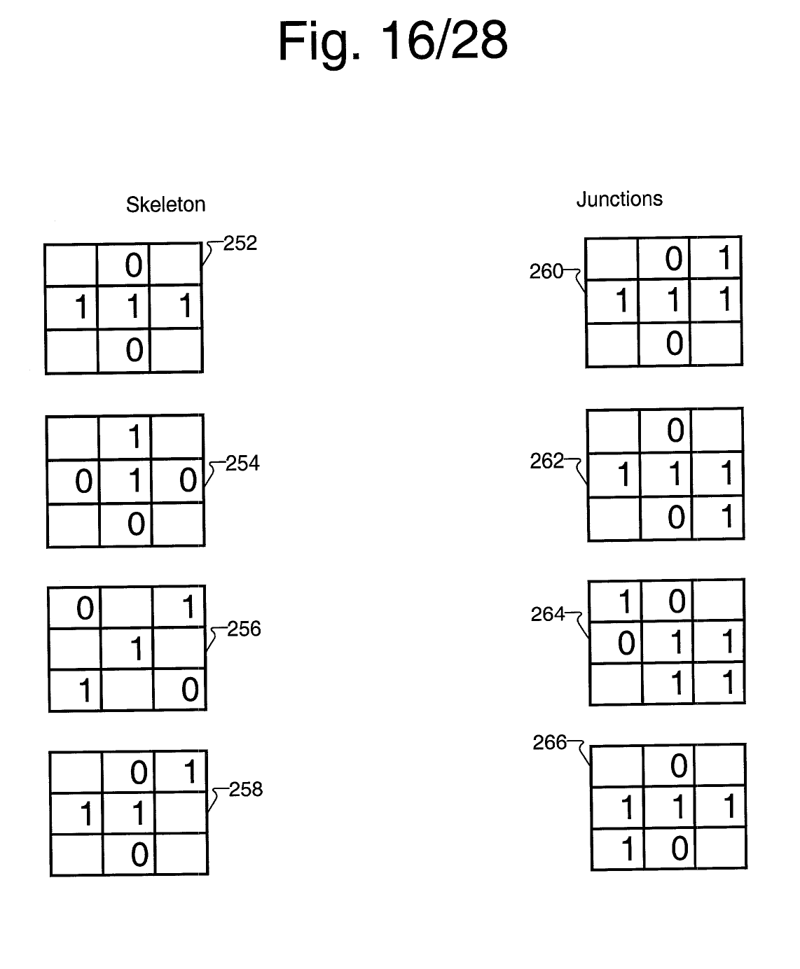

FIG. 16 shows one way in which the selection between “v” and p can be made. Various other ways may be employed to determine whether a pixel corresponds to a portion which is widening in a permissible manner, such as at a junction. When the “v/p” indicator is generated, it is assumed to be in the center of a nine pixel grid. In each grid 252-266 shown in FIG. 16, a “1” indicates a pixel eroded in the current erosion cycle. A “0” indicates a pixel eroded in the previous erosion cycle. When the arrangement of the pixels matches one of the grids 252-254, it is indicated to be fully skeletonized and the “v/p” indicator is replaced with a “v” indicator. Subsequent “n” values will be considered as nicks with respect to a preceding vector portion.

However, when the evaluation of the pixels matches one of the grids 260-266, indicated as a Junction, the “v/p” indicator is replaced with a “p” indicator, indicating that the vector has terminated. It is appreciated that each of the grids 260-266 illustrates a situation in which a pattern portion becomes wider at the end of a vector portion in a permissible manner. Such an occurrence may be found, for example, at various conductor junctions, or at the entrance into a round pad or along a pattern portion that slopes up from a relatively narrow pattern portion to a relatively wide pattern portion. The selection of a nine pixel grid instead of a larger grid is for the sake of processing speed, and larger grids can be used. Likewise, the prior set up and classification of grids as relating to protrusions or to junctions is made according to the judgment of the designer.

The grids, together, may be thought of as proximal reference information. The determination of a defect (in this case, a protrusion indication “p”) is therefore based not only on proximal width information, but also on predetermined proximal reference information.

Reference is now made to FIG. 17 which illustrates an embodiment of the invention operative to detect the presence of protrusions in patterns, such as on circuit boards. The detection of protrusions is important, for example, to detect the presence of short circuits between adjacent conductors. An image of two conductors 750 and 752, indicated by small x's, are separated by a substrate 754. Conductor 750 has a protrusion 756 and conductor 752 has a protrusion 758.

In accordance with an embodiment of the invention the image of substrate 754 separating conductors 750 and 752, with the exception of a contour region 760, indicated by O's, immediately adjacent conductors 750 and 752, is artificially painted to appear as a conductor. The painted portion of substrate 754 is indicated by capital X's.

In order to ascertain the presence of protrusions in conductors 750 and 752, the painted portion of substrate 754 is eroded using any conventional morphological erosion algorithm. The resulting width data is recorded and analyzed to detect nicks in the manner described hereinabove. Erosion and analysis of painted portion 754 may be conducted prior to, subsequent to or simultaneously with the morphological erosion of conductors 750 and 752. Nicks in the painted portion 754 correspond to protrusions in conductors 750 and 752. By first painting substrate portions to appear as conductors, it is possible detect both nicks and protrusions by using only morphological erosion processes.

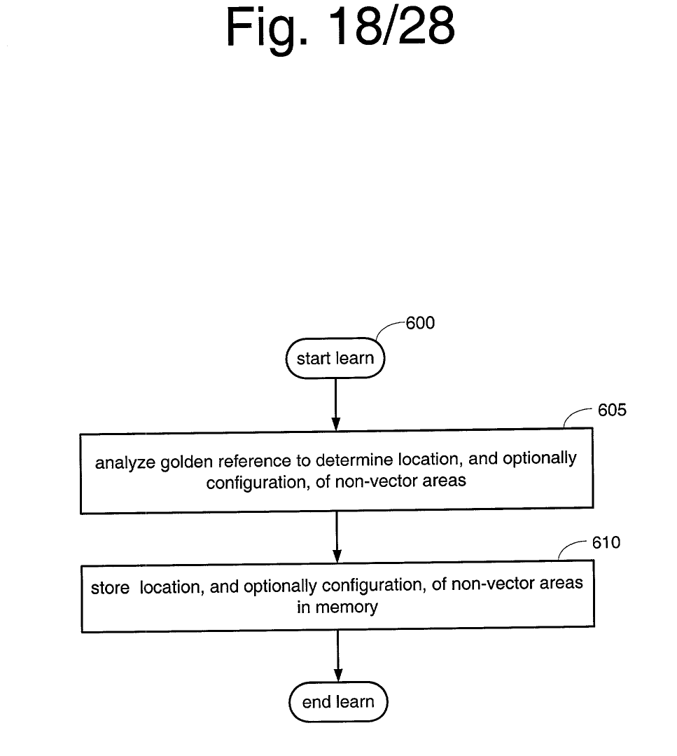

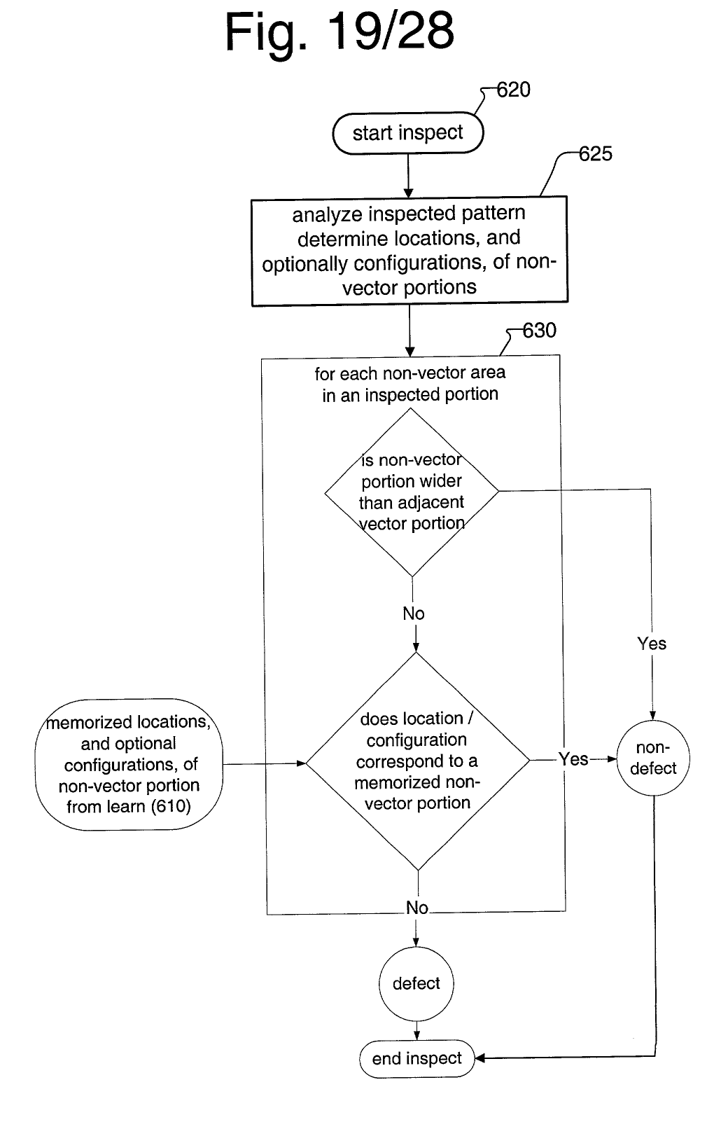

Reference is now made to FIGS. 18 and 19 which are a flow diagrams of an embodiment of the invention employing a first learn phase and a subsequent inspection phase. In accordance with such embodiment, an initial learn phase begins with step 600. In step 605, all of the various pattern portions of an image of a golden circuit board, namely an image of a circuit board which is known to be non-defective, are evaluated to determine the locations of all vector portions, as well as the locations, and optionally the configuration, of all non-vector portions. It is noted that the learn phase need not be performed, and in some preferred embodiments is not performed, on an image of an actual non-defective board. Rather, in accordance with some embodiments of the invention, a computer model, such as a computer aided manufacturing (CAM) file of a circuit to inspected, is used to provide an input for producing an reference in the learn phase. The locations, and optionally the configuration, of all non-vector portions are stored in a memory in step 610. In some embodiments of the invention, only the non-vector locations which correspond to changes in uniform width are stored in memory, while other non-vector portions are ignored. It is appreciated that optionally the location of vector portions may also be stored in memory.

By using a CAM file or an actual non-defective board, no true defects should be present in the image. Thus any non-uniform width indications generated in the learn phase are deemed as being acceptable occurrences of non-uniform width, and therefore are not flagged as defects during the subsequent inspection of actual circuit boards.

A subsequent inspection phase begins with step 620 in the flow diagram of FIG. 19. An image of a circuit board to be inspected is analyzed, and the locations in the electrical circuit pattern of all non-vector portions are determined in step 625. Optionally, the respective configurations of each of the non-vector portions are also determined. The configuration is, for example, a width indicia pattern as described with reference to FIGS. 10-17.

In step 630 each non-vector portion is evaluated to determine whether it is proximate to a vector area so as to potentially constitute a defect, and if yes whether it is at the same location, and optionally whether it has the generally the same configuration (to within accepted tolerances), as one of the non-vector portions stored in memory. If the non-vector area follows a vector area and the non-vector area is wider than the vector area, then it is not a defect. However, if the non-vector area is not wider than the vector area, then it needs to be ascertained whether the location and optionally the configuration of a non-vector portion in the image of an inspected circuit is the same as a corresponding non-vector portion stored in memory. If yes, then the inspected non-vector portion is considered to be not defective. This may occur, for example, if the non-vector portion is a corner or connects two vector portions of different width.

However, if the location of a non-vector portion does not correspond to the location of a non-vector portion stored in memory, then a defect is indicated. Optionally, if the location of a non-vector portion in the image of an inspected board does correspond to the location of a non-vector portion stored in memory, but its configuration is different from the configuration of a non-vector portion at a corresponding location stored in memory, then a defect may also be indicated.

It is noted that some embodiments relate to an inspection system that may be used to make defect determinations “on the fly” using proximal width information. That is, an image of a circuit board being inspected could be obtained, and the image processed to identify defects, in particular line width defects, based on analysis of the image without reference to an externally supplied tolerance. However in general, the inventors have found that it faster to operate in two phases, namely the learn phase and the inspection phase.

It is noted that in embodiments of the present embodiment, various different ranges of line widths are automatically accommodated. For example, in the learn phase, a first board pattern segment may be determined to be a vector with a width of 10 units, and a second board pattern segment may be determined to be a vector with a width of 8 units. The line width of the vector portions may be stored in memory and used to evaluate whether a conductor portion is acceptably wide. In such embodiment, all that would need to be set is a tolerance, and not a nominal line width. Thus, if the tolerance is set to 1 unit, then the acceptable limits on width for the first board pattern segment are 9 to 11 units and the acceptable limits on width for the second board pattern segment are 7 to 9 units.

During an inspect phase of operation, in which actual circuit boards 16 are inspected, these different ranges can be used without ambiguity. That is to say, when inspecting a board pattern segment of a circuit board 16 in the expected position of the first board pattern segment learned during the learn mode, the range of values of 9 to 11 units is used. When inspecting a board pattern segment of a circuit board 16 in the expected position of the second board pattern segment, then the range of values of 7 to 9 units is used.

Another way to put this is to say that the system provides, in learn mode, for the automated, offline determination of a plurality of acceptable width ranges. Furthermore, the system provides, in inspect mode, an inspection reference image with non-global acceptable line width ranges.

A further embodiment provides for a process for manufacturing circuit boards, in which adjustments are made in the fabrication equipment in response to the defect indications rendered during inspection.

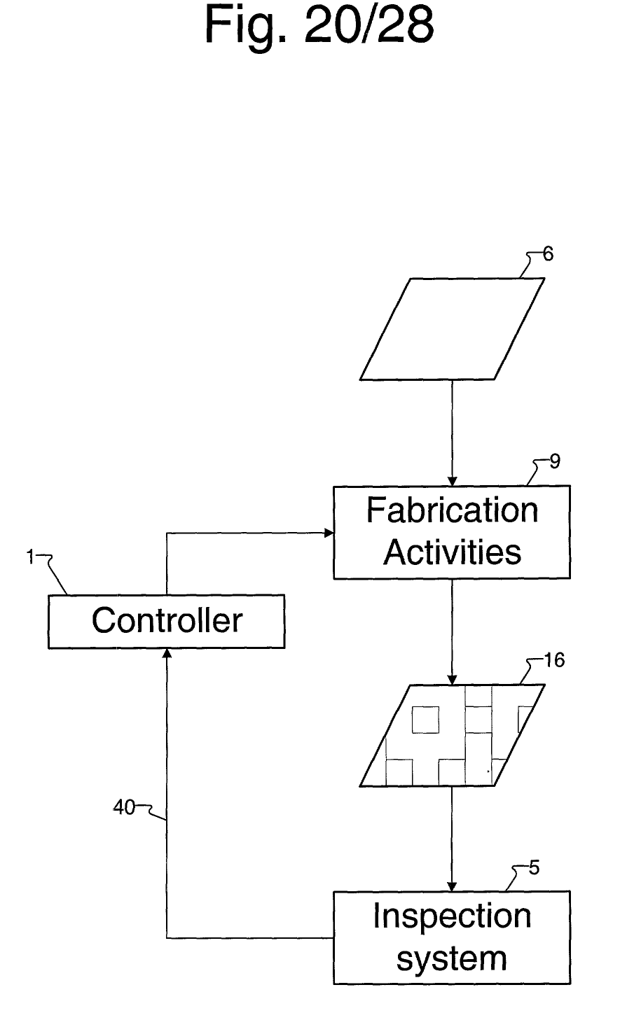

FIG. 20 shows a fabrication and inspection system, in which a controller 1 controls fabrication activities 9 that produce a printed circuit board 16 from input materials 6. The printed circuit board 16 is input to an inspection system 5, which undertakes an inspection process as in one of the previously described embodiments. A report of defect indications 40 is provided in a feedback loop to the controller 1. Based on the indications of defects, the controller may, through an automatic or manual process, adjust the assembly activities 9 in response thereto. That is to say, the controller may cause equipment used during fabrication activities 9 to be adjusted, so that the assembly activities are performed in a manner that is projected to produce another printed circuit board 16 with more desirable inspection results.

A typical type of defect employed in such a fabrication and inspection system is line width. It is appreciated that typically uniform changes in line width are the result of improper adjustment of exposure and/or etching processes used in the manufacture of printed circuit boards. Thus a histogram of the widths of vector portions in an inspected circuit board, obtained as described hereinabove, is recorded and evaluated with reference to a histogram of the width of vector portions in golden board. The evaluation may be made for an entire board on a global basis, or for selected portions of the board. Controller 1 may then be used to adjust exposure and/or etching processes so as to bring the width of uniform vector portions of conductor into accord with design specifications.

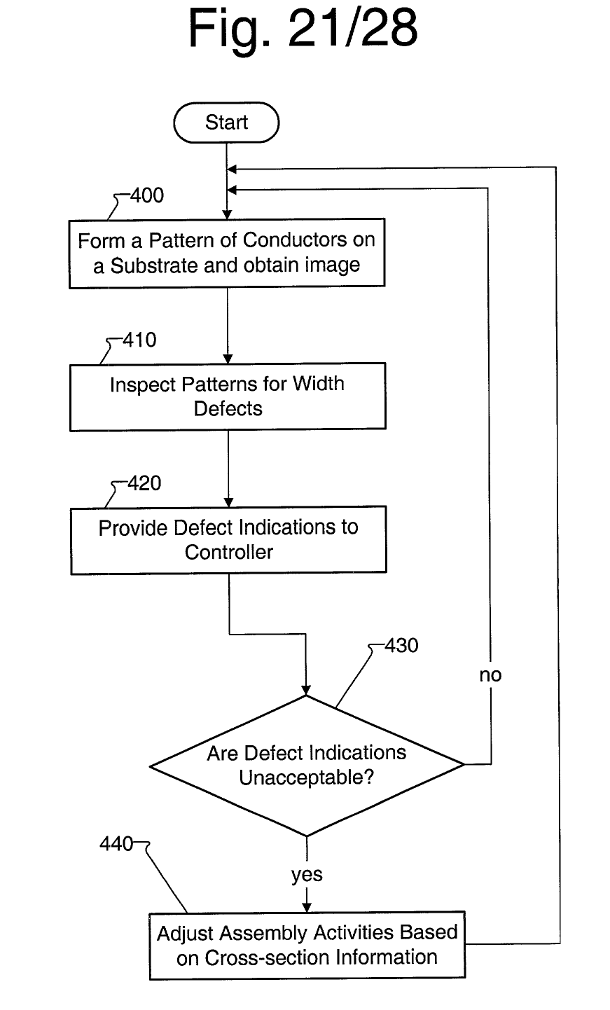

FIG. 21 shows a flow diagram that illustrates the steps just described. In particular, in step 400, a conductor is formed on a substrate, and in image is obtained so that the patterns (i.e., the conductor areas, the non-conductor areas, or both) can be inspected. The printed circuit board image is provided to the inspection system 5. In step 410, the image of the printed circuit board 16 is inspected for line width defects as described hereinabove.

The defect indications report 40 is produced from analysis of the line widths and is provided to the controller 1 in step 420. In step 430, the controller determines whether the defect indications are acceptable. That is to say, the controller determines whether the defect indications indicate a problem that needs correction, or does not indicate such a problem. If there is a problem that needs correction, processing continues from step 430 to step 440, in which the controller adjusts the assembly activities in response to the defect indications prior to resuming production at step 400. If there is not a problem that needs correction, processing may continue from step 430 to step 400, and production may continue as before.

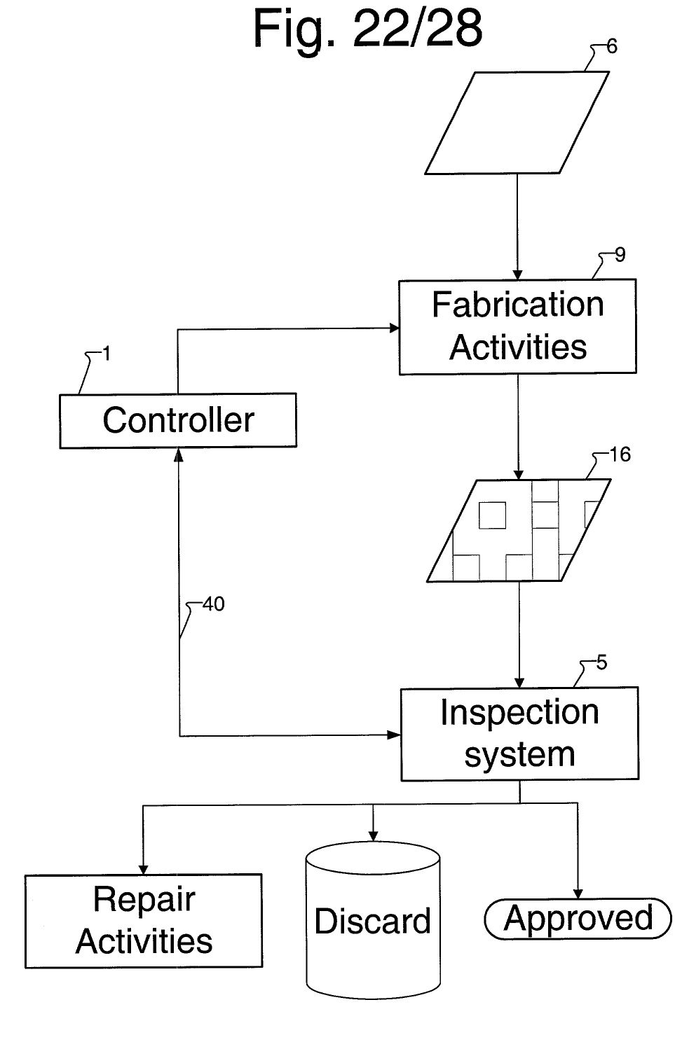

In a still further embodiment, there is provided a process for manufacturing circuit boards, in which a decision is made as to whether to repair, to discard, or to use a board based on the defect indications rendered during inspection. FIG. 22 shows such a system employing method of manufacturing electrical circuits, in which circuit boards are inspected as described hereinabove. The method of FIG. 22 is similar in many ways to the method illustrated in FIG. 20 except that the report 40 provided by the inspection system 5 is used to determine whether to undertake repair activities, to discard the printed circuit board, or to approve the printed circuit board. A decision making process in this embodiment focuses not on the modification of the fabrication activities alone, but on facilitating further automatic or manual inspection of defective locations, and ultimately the repair of those defective portions of the printed circuit board substrate 16 which are deemed repairable.

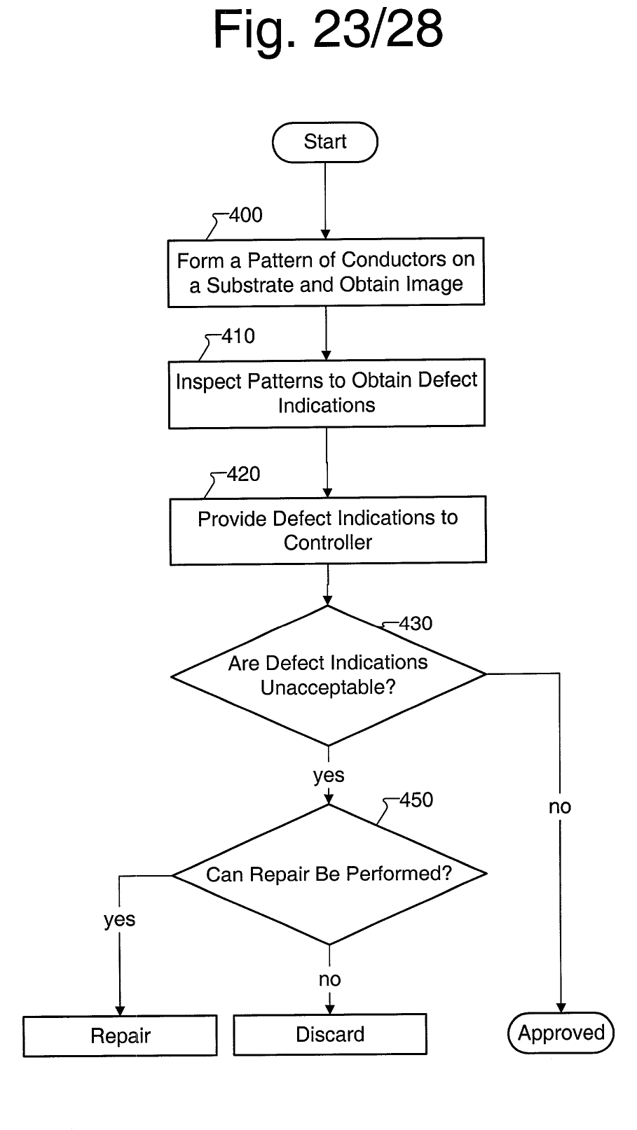

FIG. 23 is a flow diagram that illustrates the steps just mentioned. In particular, steps 400-420 are the same as mentioned above with respect to FIG. 21. In step 430, however, if the defect indication report indicates that all of the width violations are in fact not defects, then the printed circuit board 16 is approved. On the other hand, if the width violations are not deemed to correspond to actual defects, then in step 430, processing continues to step 450 in which it is determined whether repair of the defect can or cannot be performed. In preferred embodiments of the invention, this verification is performed off-line in a dedicated verification and repair station such as a VRS-4™ verification station available from Orbotech Ltd. of Yavne, Israel. If it is determined that repair can be performed, then processing continues with the printed circuit board 16 being repaired in the step indicated as “repair”. If it is determined that repair cannot be performed, then the printed circuit board 16 is discarded.

Another way of saying this is that the circuit is discarded or repaired in response to the defect determinations obtained through an inspection process according to one or more of the above-identified embodiments.

An overlapping tolerance range example will now be provided to help illustrate the advantages and applicability of the invention.

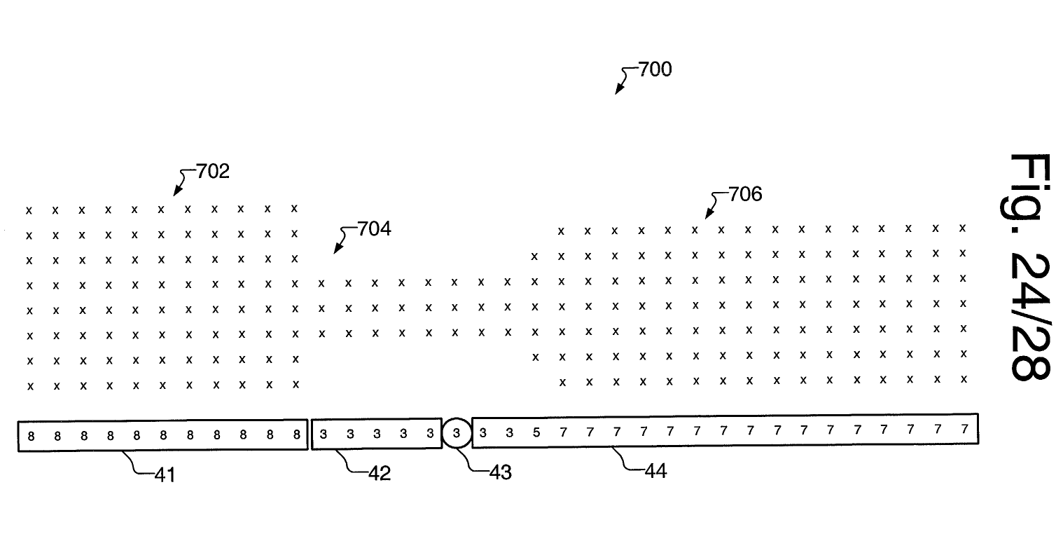

FIG. 24 shows an exemplary pattern 700 subjected to the inspection operation according to FIG. 6. It may be assumed in this example that the pad 702 at the far left is a rectangular pad, such as an SMT pad, and a first conductor portion 704 extends from the pad 702. The first conductor portion 704 throats out to a wider second conductor portion 706.

In this example, the pattern is on an actual circuit board under inspection. The first conductor portion 704 extending from the pad was to have a line width of 4, with an acceptable tolerance of plus or minus 1 (i.e., widths of 3 to 5 are accepted). The wider second conductor was to have a line width of 6, with the same tolerance (i.e., widths of 5 to 7 being acceptable.

It is clear, then, that the acceptable range of widths for the two conductor portions 704 and 706 respectively overlaps at 5 pixels. Using a conventional system, a proper inspection could not easily be performed. For example, setting a single universal width to 6 (plus or minus 1) would result in the first conductor being flagged as an error because it has an actual width of 3. Setting it to 4 (plus or minus 1) would result in the second conductor being flagged as an error because it has an actual width of 7. Even setting a universal width to 5 (plus or minus 1) in an attempt to reach a “happy medium” would not work, because the first and second conductors would both be flagged as having line width violations. Moreover, by extension of the tolerance, for example to plus or minus 2 could accommodate first conductor portion, provided it is on the wide of an acceptable range, but not the thin side. Likewise, the extended tolerance could accommodate second conductor portion 706, provided that it is on the thin side of the acceptable range, but not on the wide side.

Moreover, as discussed hereinabove, if two global widths with overlapping tolerances are provided, then an uncertainty results in the conventional approach whenever the width of an inspected conductor falls within the overlapping range.

According to the inspection method described herein, however, the rectangular pad 702 would be classified as a vector and, hence, acceptable. Likewise, the first conductor portion 704 and the second conductor 706 would both be classified as vectors and acceptable. Finally, the throat 43 between the first and second vectors would be initially flagged as a defect with reference to vector 44 because it is two units less than the width of vector 44. However with respect to vector 42, throat 43 would not be flagged because it is wider than vector 42. Upon application of further rules, such as a location between vectors of different width, or following comparison to a reference, throat 43 would either be recorded as an event in a learn mode, or would be filtered out in an inspection mode. In view of the foregoing, it is clear that overlapping ranges do not present a problem in the inspection method according to any of the foregoing embodiments.

The system thus provides for inspection of line widths without using a global width parameter (i.e., using non-global width parameters).

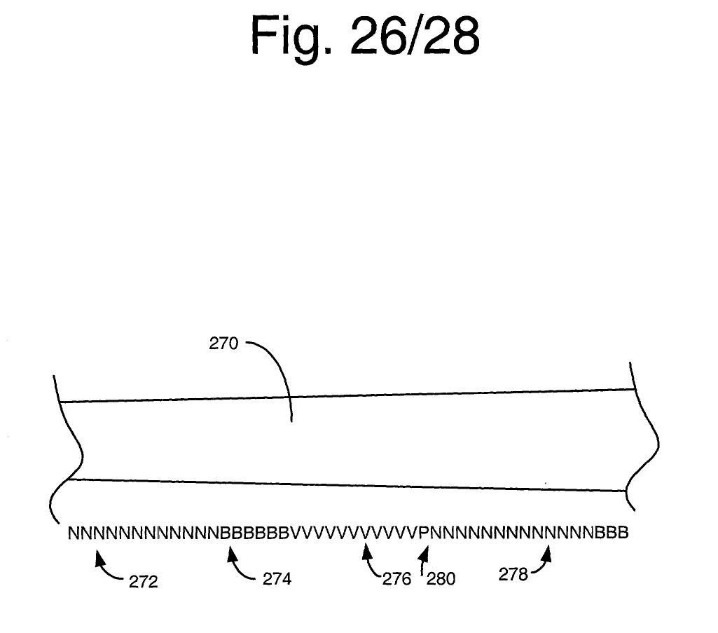

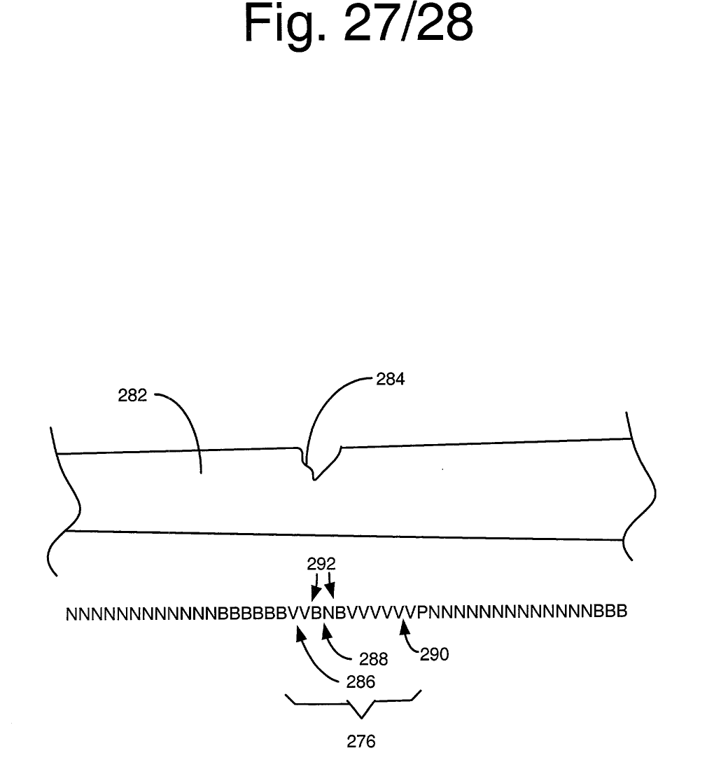

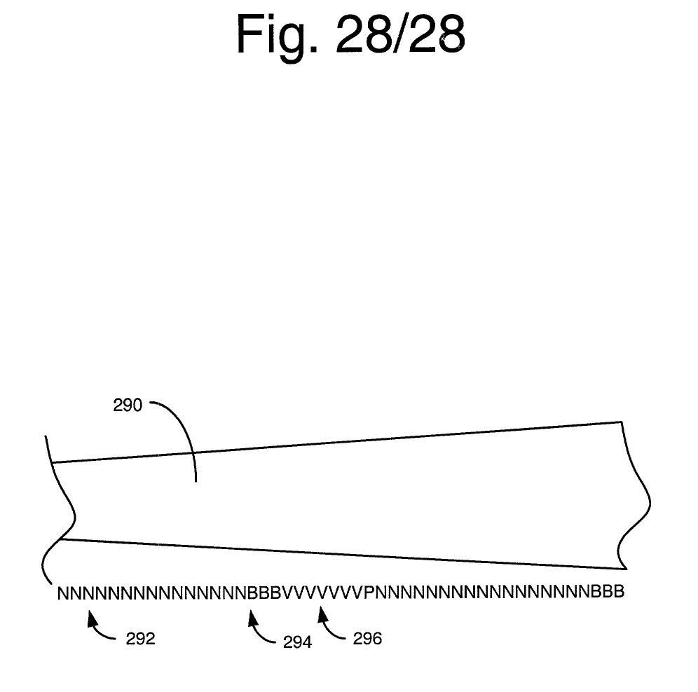

Reference is made to FIG. 26 which is an illustration of a properly formed conductor having a continuously changing width and to FIGS. 27 and 28 which illustrate the detection of defects in conductors having a continuously changing width. It is appreciated that one application of a system for inspecting circuit boards that avoids requiring a global parameter is in the improved inspection capability relating to circuit boards that have conductors, such as conductor 270, whose widths continuously change from a first relatively narrow end to a second relatively wide end (i.e., at least one sloped conductor having a first width at a first end, a second width at a second end, and a sloping edge connecting the first end and said second end). The change in width can be analyzed with respect to a predetermined pattern of width indicia to determine the presence or absence of a change that is indicative of a width defect. Such inspection may be part of the above described manufacturing processes.

Width indicia for the conductor having a continuously changing width 270 is shown in FIG. 26. Thus a first portion 272 of conductor 270 has a string of “N” width indicator, second portion 274 of conductor 270 has “B” width indicator, and third portion 276 of conductor 270 has “V” width indicator, and a fourth portion 278 has “N” indicator, resulting from the wrap around manner in which width indicia are assigned, as described above with reference to FIGS. 10-14 and 25. An additional portion 280 of conductor 270 has a “P” width indicator.

In accordance with an embodiment of the invention, a width analyzer searches for segments of “N” width indicia which are adjacent to “V” width indicia, which are indicative of reductions in conductor width. In a learn mode, as described above, such portions of changing width are learned as being permissible, while in an inspect mode such portions of changing width are deemed potential defects, and are further evaluated to determine whether there is a corresponding permissible change of width in the reference.

It is seen that along conductor 270 portion 272 is separated from portion 276 by section 274. It is also seen that portion 278 would be adjacent to portion 276 but for the “P” indicator in portion 280. Portion 280 signifies that the adjacency of “V” and “N” width indicia in portions 276 and 280 is indicative of an increasing width and is therefore not considered a defect.

In some embodiments of the invention, in a learn mode the quantity of “B” indicators in portion 274 is quantified, and the slope of the conductor is trigonometrically calculated using the length of the portion 274 and its height (derived from the number of “B” eroded pixels that can be assigned a “B” value, e.g. 2 pixels in LUT 200 or 1 pixel in LUT 250).

A portion of inspected conductor having a continuously changing width 282, but having a nick defect 284 is seen in FIG. 27. The defect occurs in a portion corresponding to portion 276 of FIG. 26, which is now indicated by portions 286, 288, 290 and 292. Portion 290 is a vector. Because portion 290 is separated from the nick portion 288 by only a single “B” (portion 292), a possible nick is indicated. Because there is no corresponding change in width indication in reference portion 270, the indicated nick is deemed a defect.

A portion of inspected conductor having a continuously changing width 294, but having an improper slope is seen in FIG. 28. Because of the slope the dispersion of width indicia is different from that of conductor 270 in FIG. 26. Thus in accordance with an embodiment of the invention, comparison of the quantity of lesser quantity of “B” width indicia in portion 296, as compared to the quantity of “B” width indicia that would be expected from portion 274 is indicative of an improper slope in conductor 294, and may be reported as a defect.

It is appreciated from the foregoing, that by analyzing the relative changes in width of conductors it is possible to detect various different types of defects, including nick defects along conductors of continuously changing width, and defects related to the slope characteristic of conductors having a continuously changing width.

It will be appreciated by persons skilled in the art that the present invention is not limited by what has been particularly shown and described hereinabove. Rather, the scope of the present invention includes both combinations and subcombinations of the features described hereinabove as well as modifications and variations thereof which would occur to a person of skill in the art upon reading the foregoing description and which are not in the prior art.

There is claimed:

1. An electrical circuit inspection method, comprising:
acquiring an image representing a board pattern of a circuit board;
obtaining width information relating to said board pattern; and
making a defect determination for said board pattern based on an analysis of proximal width information.

2. The inspection method as set forth in claim 1, wherein said analysis of said proximal width information includes identification of a non vector portion of said board pattern.

3. The inspection method as set forth in claim 2, wherein said identifying of said non vector portion is performed using a look-up table having width indicia in separate processing channels.

4. The inspection method as set forth in claim 3, wherein, when said proximal width information for said defect determination is obtained from just one channel, a defect is indicated.

5. The inspection method as set forth in claim 4, wherein said proximal width information for said just one channel indicates a vector preceding and succeeding said non vector portion.

6. The inspection method as set forth in claim 2, wherein said proximal width information is obtained using a morphological process.

7. The inspection method as set forth in claim 6, wherein said morphological process is an erosion process.

8. The inspection method as set forth in claim 2, further comprising identifying an indicia pattern of said non vector portion.

9. The inspection method as set forth in claim 8, further comprising:
providing an indicia pattern dictionary, and
characterizing said non vector portion based on a correspondence between said indicia pattern of said non vector portion and a predetermined indicia pattern in said indicia pattern dictionary.

10. The inspection method as set forth in claim 1, wherein said board pattern is a conductor area.

11. The inspection method as set forth in claim 1, wherein said board pattern is a non-conductor area.

12. A method for manufacturing electrical circuits, comprising:
forming at least one board pattern on a substrate;
acquiring an image representing said at least one board pattern and said substrate;
evaluating said image to obtain width dimension values corresponding to the width of said at least one board pattern at a multiplicity of locations;
repairing a conductor or discarding a substrate at least partially in response to an indication of an aberration in the width of board patterns, said indication being obtained from analysis of proximal width information representing localized changes in board pattern width dimension values.

13. The manufacturing method as set forth in claim 12, wherein said analysis of said proximal width information includes identification of a non vector portion of said board pattern.

14. The manufacturing method as set forth in claim 13, wherein said identifying of said non vector portion is performed using a look-up table having width indicia in separate processing channels.

15. The manufacturing method as set forth in claim 14, wherein, when said proximal width information for said defect determination is obtained from just one channel, a defect is indicated.

16. The manufacturing method as set forth in claim 15, wherein said proximal width information for said just one channel indicates a vector preceding and succeeding said non vector portion.

17. The manufacturing method as set forth in claim 13, wherein said proximal width information is obtained using a morphological process.

18. The manufacturing method as set forth in claim 17, wherein said morphological process is an erosion process.

19. The manufacturing method as set forth in claim 13, further comprising identifying an indicia pattern of said non vector portion.

20. The manufacturing method as set forth in claim 19, further comprising:
providing an indicia pattern dictionary, and
characterizing said non vector portion based on a correspondence between said indicia pattern of said non vector portion and a predetermined indicia pattern in said indicia pattern dictionary.

21. The manufacturing method as set forth in claim 12, wherein said board pattern is a conductor area.

22. The manufacturing method as set forth in claim 11, wherein said board pattern is a non-conductor area.

23. An electrical circuit inspection method, comprising:
automatically producing, in a learn mode, a reference image having non-global acceptable line width ranges; and
inspecting a circuit board, in an inspect mode, using said reference image.

24. The inspection method as set forth in claim 23, wherein said reference image is produced by:
acquiring an image representing a board pattern of a circuit board;
obtaining width information relating to said board pattern; and
making a defect determination for said board pattern based on an analysis of proximal width information.

25. The inspection method as set forth in claim 24, wherein said image is obtained from a non-defective representation of a circuit board.

26. The inspection method as set forth in claim 25, wherein said non-defective representation is a CAM image.

27. The inspection method as set forth in claim 24, wherein said analysis of said proximal width information includes identification of a non vector portion of said board pattern.

28. The inspection method as set forth in claim 27, wherein said identifying of said non vector portion is performed using a look-up table having width indicia in separate processing channels.

29. The inspection method as set forth in claim 28, wherein, when said proximal width information for said defect determination is obtained from just one channel, a defect is indicated.

30. The inspection method as set forth in claim 29, wherein said proximal width information for said just one channel indicates a vector preceding and succeeding said non vector portion.

31. The inspection method as set forth in claim 27, wherein said proximal width information is obtained using a morphological process.

32. The inspection method as set forth in claim 31, wherein said morphological process is an erosion process.

33. The inspection method as set forth in claim 27, further comprising identifying an indicia pattern of said non vector portion.

34. The inspection method as set forth in claim 33, further comprising:
providing an indicia pattern dictionary, and
characterizing said non vector portion based on a correspondence between said indicia pattern of said non vector portion and a predetermined indicia pattern in said indicia pattern dictionary.

35. The inspection method as set forth in claim 24, wherein said board pattern is a conductor area.

36. The inspection method as set forth in claim 24, wherein said board pattern is a non-conductor area.

37. The inspection method as set forth in claim 23, wherein said reference comprises:
a map of conductors;
a first indication in said map of the width of a first plurality of conductors at a first multiplicity of locations; and
a second indication in said map of the width of a conductor at a second location.

38. A method for manufacturing electrical circuits comprising:
forming a portion of electrical circuit pattern on a substrate, said electrical circuit pattern including at least one sloped conductor having a first width at a first end, a second width at a second end, and a sloping edge connecting said first end and said second end;
inspecting said electrical circuit pattern;
detecting the presence or absence of defects along said at least one sloped conductor; and
discarding or repairing said electrical circuit pattern in response to said inspecting.

39. A method for inspecting electrical circuits comprising:
acquiring an image of an electrical circuit to be inspected;
identifying regions corresponding to conductors and regions not corresponding to conductors;
morphologically processing regions not corresponding to conductors to detect defects in conductors.

40. A method for inspecting electrical circuits according to claim 39 and wherein said morphologically processing regions not corresponding to conductors comprises artificially defining at least a part of said regions not corresponding to conductors as pseudo conductors.

41. A method for inspecting electrical circuits according to claim 39 and wherein said morphologically processing includes morphologically eroding said regions not corresponding to conductors and identifying nicks in said regions not corresponding to conductors.

42. A method for inspecting electrical circuits according to claim 41 and wherein said morphologically processing includes correlating nicks in said regions not corresponding to conductors to protrusions in said regions corresponding to conductors.

43. A method for preparing a reference for use in inspecting electrical circuits, comprising:
acquiring an image of an electrical circuit believed to be not defective;
analyzing said image to detect the presence of image portions indicative of nicks in conductors; and
discarding from use as a reference an image which has one or more portions that are indicative of nicks.

44. A method according to claim 43 and wherein said analyzing includes acquiring width data for a plurality of image portions corresponding to conductors in said electrical circuit.

45. A method according to claim 44 and wherein said analyzing further includes detecting width defects from evaluation of proximal width data based on the application of a rule.

46. A method according to claim 45 and wherein the rule is that a nick is present when a portion of conductor of relatively narrow width is located between two adjacent portions of generally uniform relatively wide width.

47. A method for preparing a reference for use in inspecting electrical circuits, comprising:
acquiring an image of an electrical circuit believed to be not defective;
analyzing said image to detect the presence of image portions indicative of nicks in conductors; and
in images having portions that are indicative of nicks, masking at least some of said portions that are indicative of nicks.

48. A method according to claim 47 and wherein said analyzing includes acquiring width data for a plurality of image portions corresponding to conductors in said electrical circuit.

49. A method according to claim 48 and wherein said analyzing further includes detecting width defects from evaluation of proximal width data based on the application of a rule.

50. A method according to claim 49 and wherein the rule is that a nick is present when a portion of conductor of relatively narrow width is located between two adjacent portions of generally uniform relatively wide width.
